(19) United States
(12) Patent Application Publication
(10) Pub. No.: US 2025/0006789 A1
(43) Pub. Date: Jan. 2, 2025

(54) SEMICONDUCTOR DEVICE

(71) Applicant: SAMSUNG ELECTRONICS CO., LTD., Suwon-si (KR)

(72) Inventors: Bo Kyung SHIN, Suwon-si (KR); Sang Min CHO, Suwon-si (KR); Jeong Yong CHOI, Suwon-si (KR); Dong Woo KANG, Suwon-si (KR); Hong Bae PARK, Suwon-si (KR)

(73) Assignee: SAMSUNG ELECTRONICS CO., LTD., Suwon-si (KR)

(21) Appl. No.: 18/425,857

(22) Filed: Jan. 29, 2024

(30) Foreign Application Priority Data
Jun. 29, 2023 (KR) 10-2023-0084013

(51) Int. Cl. H01L 29/06; H01L 29/423; H01L 29/66; H01L 29/775; H01L 29/786

(52) U.S. Cl. CPC H01L 29/0673; H01L 29/42392; H01L 29/6656; H01L 29/775; H01L 29/78696; H01L 29/66439

(57) ABSTRACT

A semiconductor device includes an active pattern including a lower pattern extending a first direction and a plurality of sheet patterns spaced apart from the lower pattern in a second direction, the plurality of sheet patterns including an uppermost sheet pattern, a plurality of gate structures disposed to be spaced apart from each other in the first direction on the active pattern and including gate electrodes extending in a third direction and gate spacers on sidewalls of the gate electrodes and a source/drain pattern disposed between the gate structures adjacent to each other and including a semiconductor liner film and a semiconductor filling film on the semiconductor liner film, wherein the semiconductor liner film covers a portion of an upper surface of an uppermost sheet pattern.

### CROSS-REFERENCE TO RELATED APPLICATION

This application claims priority from Korean Patent Application No. 10-2023-0084013 filed on Jun. 29, 2023 in the Korean Intellectual Property Office, the disclosure of which is incorporated herein by reference in its entirety.

### BACKGROUND

### 1. Technical Field

Apparatuses and methods consistent with example embodiments relate to a semiconductor device, and more particularly, to a semiconductor device including a field-effect transistor such as a multi-bridge channel field effect transistor (MBCFET™).

### 2. Description of the Related Art

As one of the scaling techniques for increasing a density of semiconductor devices, a multi-gate transistor in which a multi-channel active pattern (or silicon body) having a fin or nanowire shape is formed on a substrate and a gate is formed on a surface of the multi-channel active pattern has been proposed.

Since such a multi-gate transistor uses a three-dimensional channel, it is easy to perform scaling. In addition, it is possible to improve current control capability even without increasing a length of the gate of the multi-gate transistor. In addition, it is possible to effectively suppress a short channel effect (SCE) in which a potential of a channel region is affected by a drain voltage.

### SUMMARY

One or more aspects of the present disclosure provide a structure and an operating method of a semiconductor device for improving performance and reliability of the semiconductor device.

According to an aspect of the present disclosure, a semiconductor device may include: an active pattern including a lower pattern extending a first direction and a plurality of sheet patterns spaced apart from the lower pattern in a second direction; a plurality of gate structures disposed on the active pattern and including gate electrodes extending in a third direction and gate spacers disposed on sidewalls of the gate electrodes; and a source and drain pattern disposed between the plurality of gate structures adjacent to each other and including a semiconductor liner film and a semiconductor filling film on the semiconductor liner film, wherein an uppermost sheet pattern of the plurality of sheet patterns may include an upper surface and a bottom surface opposite to the upper surface, in the second direction, the bottom surface of the uppermost sheet pattern may face the lower pattern, and the semiconductor liner film may cover a portion of the upper surface of the uppermost sheet pattern.

The gate spacer may include a first spacer and a second spacer, the first spacer is disposed between the gate electrode and the second spacer, the second spacer includes an extending portion of the second spacer extending in the third direction along the sidewall of the gate electrode, and a protruding portion of the second spacer protruding from the extending portion of the second spacer in the first direction, the protruding portion of the second spacer may include a first surface facing the sheet pattern and a second surface opposite to the first surface of the protruding portion of the second spacer, and the semiconductor liner film is in contact with the first surface of the protruding portion of the second spacer.

The semiconductor device may include a etch stop film disposed on the source and drain pattern and in contact with the second spacer, wherein the etch stop film may be in contact with the second surface of the protruding portion of the second spacer.

A portion of the semiconductor filling film may be disposed on the second surface of the protruding portion of the second spacer.

The first spacer may include an extending portion of the first spacer extending in the third direction along the sidewall of the gate electrode, and a protruding portion of the first spacer protruding from the extending portion of the first spacer in the first direction.

The first spacer has an I shape in a cross-sectional view.

The first spacer has a T shape rotated by 180 degrees in a cross-sectional view.

Each of the plurality of gate structure may include a gate insulating film disposed between the gate spacer and the gate electrode, and the gate insulating film is in contact with the semiconductor liner film.

The source and drain pattern may further include a semiconductor insertion film disposed between the semiconductor liner film and the semiconductor filling film, and the semiconductor liner film, the semiconductor filling film, and the semiconductor insertion film includes silicon-germanium.

According to another aspect of the present disclosure, a semiconductor pattern may include: an active pattern including a lower pattern extending in a first direction and a plurality of sheet patterns spaced apart from the lower pattern in a second direction; a plurality of gate structures disposed on the active pattern, and including gate electrodes extending in a third direction, gate spacers disposed on sidewalls of the gate electrodes, and gate insulating films disposed between the gate spacers and the gate electrodes; and a source and drain pattern disposed between the plurality of gate structures adjacent to each other and including a semiconductor liner film in contact with the gate insulating film and a semiconductor filling film on the semiconductor liner film, wherein the semiconductor liner film includes a central portion and protruding portions disposed on both sides of the central portion of the semiconductor liner film in a plan view, and the protruding portion of the semiconductor liner film protrudes in the first direction toward the gate electrode.

A width of a contact surface where the semiconductor liner film and the gate insulating film are in contact with each other in the third direction may be less than a width of the semiconductor liner film in the third direction.

Each of the plurality of sheet patterns may include an upper surface and a bottom surface opposite to each other in the second direction, each of the plurality of sheet patterns may include sidewalls connecting the upper surface and the bottom surface of the plurality of sheet patterns in the third direction, and the semiconductor liner film may cover a portion of the sidewalls of the plurality of sheet patterns.

The protruding portion of the semiconductor liner film may be in contact with the sidewall of each of the plurality of sheet patterns.

The gate spacer may include a first spacer and a second spacer, the first spacer is disposed between the gate electrode and the second spacer, the second spacer includes an extending portion of the second spacer extending in the third direction along the sidewall of the gate electrode, and a protruding portion of the second spacer protruding from the extending portion of the second spacer in the first direction, and the semiconductor liner film may be in contact with the protruding portion of the second spacer.

The protruding portion of the semiconductor liner film may overlap the first spacer in the first direction.

The first spacer may include an extending portion of the first spacer extending in the third direction along the sidewall of the gate electrode, and a protruding portion of the first spacer protruding from the extending portion of the first spacer in the first direction.

The protruding portion of the first spacer may protrude toward the gate electrode.

The first spacer may have an I shape in a plan view.

According to another aspect of the present disclosure, a semiconductor device may include: an active pattern including a lower pattern extending a first direction and a plurality of sheet patterns spaced apart from the lower pattern in a second direction; a plurality of gate structures disposed on the active pattern and including gate electrodes extending in a third direction and gate spacers disposed on sidewalls of the gate electrodes; and a source and drain pattern disposed between the plurality of gate structures adjacent to each other and including a semiconductor liner film and a semiconductor filling film on the semiconductor liner film, wherein the gate spacer may include a first spacer and a second spacer disposed between the first spacer and the gate electrode, the first spacer may include an extending portion of the first spacer extending in the third direction along the sidewall of the gate electrode, and a protruding portion of the first spacer protruding from the extending portion of the first spacer in the first direction, the protruding portion of the first spacer may include a first surface facing the plurality of sheet patterns and a second surface opposite to the first surface of the protruding portion of the first spacer, an uppermost sheet pattern of the plurality of sheet patterns may include an upper surface and a bottom surface opposite to the upper surface, in the second direction, the bottom surface of the uppermost sheet pattern may face the lower pattern, and a portion of the semiconductor liner film may be recessed between the upper surface of the uppermost sheet pattern and the first surface of the protruding portion of the first spacer.

The second spacer may include an extending portion of the second spacer extending in the third direction along the sidewall of the gate electrode, and a protruding portion of the second spacer protruding from the extending portion of the second spacer in the first direction, and the protruding portion of the second spacer may protrude toward the gate electrode.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is an example plan view for describing a semiconductor device according to some example embodiments.

FIGS. 2 and 3 are cross-sectional views taken along lines A-A and B-B of FIG. 1.

FIG. 4 is a view for describing a shape of a first sheet pattern of FIG. 2.

FIG. 5 is a plan view taken along line C-C of FIG. 2.

FIG. 6 is a plan view taken along line D-D of FIG. 2.

FIG. 7 is an enlarged view of region P of FIG. 2.

FIG. 8 is a view for describing a planar shape of a semiconductor liner film in FIGS. 5 and 6.

FIGS. 9 to 11 are views for describing a semiconductor device according to some example embodiments.

FIGS. 12 to 16 are views for describing a semiconductor device according to some example embodiments.

FIGS. 17 to 19 are views for describing a semiconductor device according to some example embodiments.

FIGS. 20 and 21 are views for describing a semiconductor device according to some example embodiments, respectively.

FIGS. 22 to 25 are views for describing a semiconductor device according to some example embodiments.

FIGS. 26 to 30 are views for describing a semiconductor device according to some example embodiments.

FIGS. 31 to 33 are views for describing a semiconductor device according to some example embodiments.

FIGS. 34 to 47 are intermediate step views for describing a method for manufacturing a semiconductor device according to some example embodiments.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

Terms “first”, “second” and the like are used herein to describe various elements or components, but these elements or components are not limited by these terms. These terms are used only to distinguish one element or component from another element or component. Therefore, a first element or component mentioned below may be a second element or component within the technical spirit of the present disclosure.

Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

A semiconductor device according to some example embodiments may include a tunneling field effect transistor (FET), a three-dimensional (3D) FET, or a two-dimensional material-based FET, and a heterostructure thereof. In addition, the semiconductor device according to some example embodiments may also include a bipolar junction transistor, a lateral double-diffused metal oxide semiconductor (LDMOS) transistor, or the like.

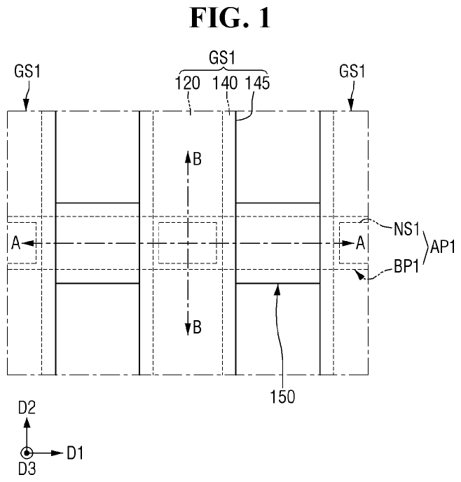

The semiconductor device according to some example embodiments will be described with reference to FIGS. 1 to 8.

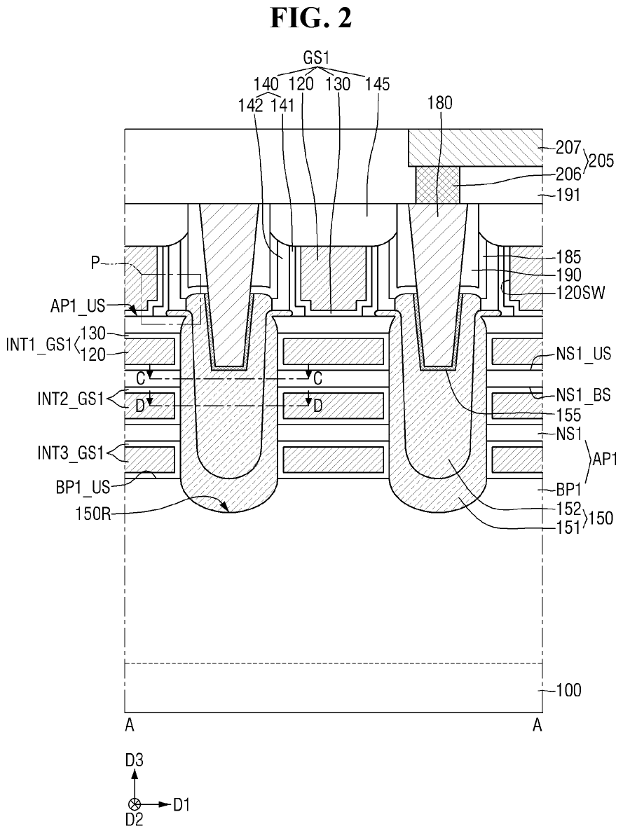

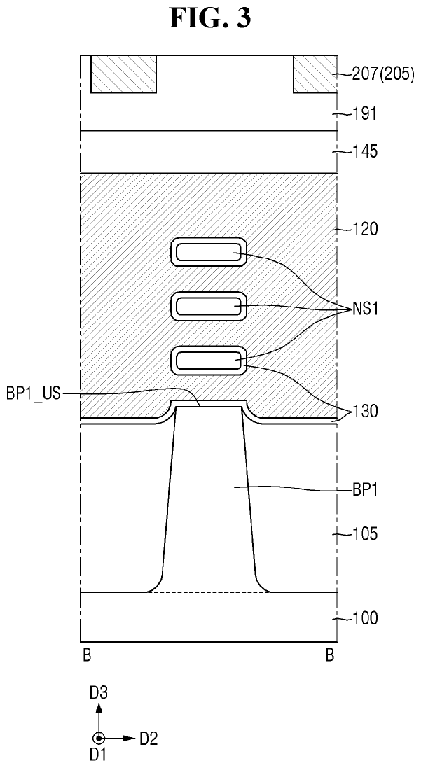

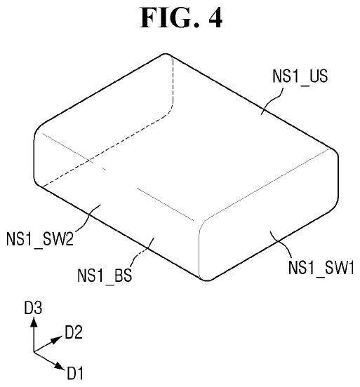

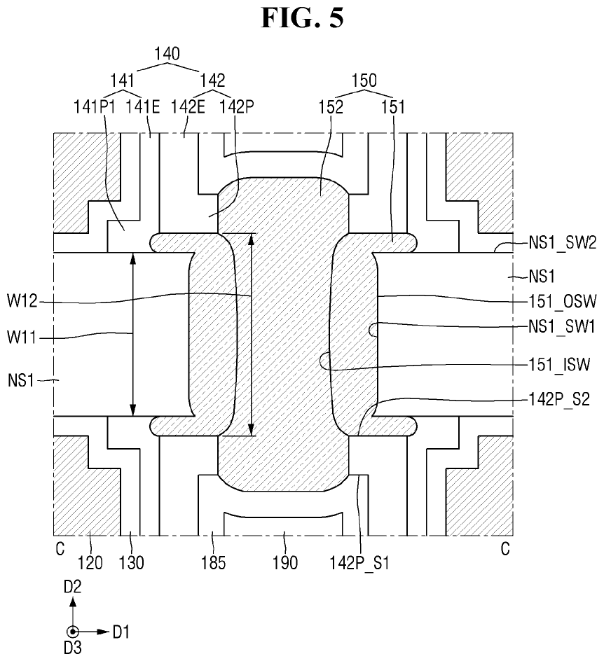

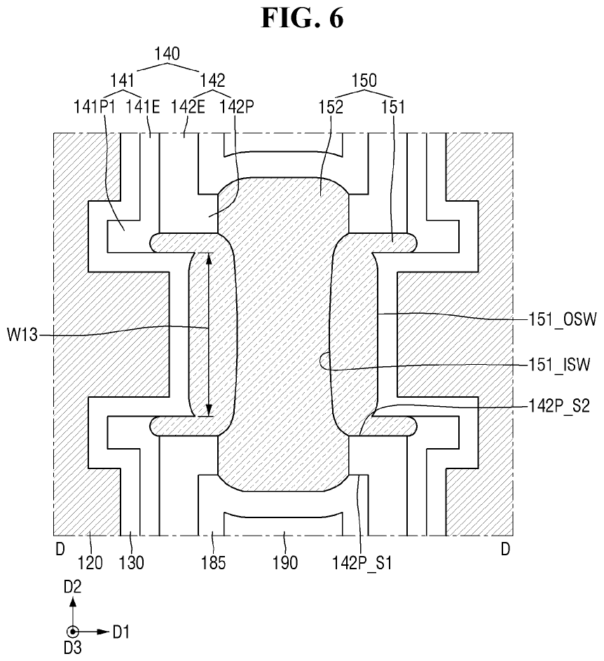

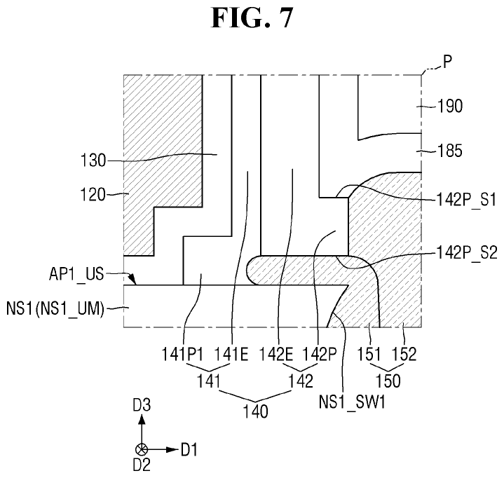

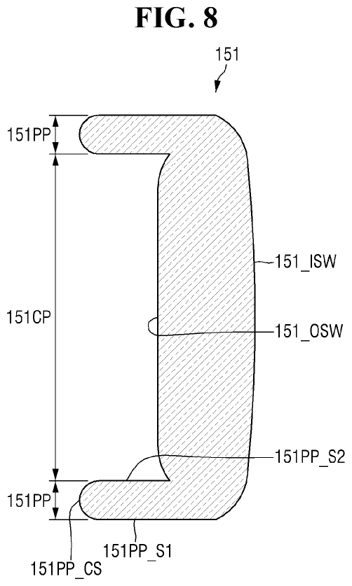

FIG. 1 is an example plan view for describing a semiconductor device according to some example embodiments. FIGS. 2 and 3 are cross-sectional views taken along lines A-A and B-B of FIG. 1. FIG. 4 is a view for describing a shape of a first sheet pattern of FIG. 2. FIG. 5 is a plan view taken along line C-C of FIG. 2. FIG. 6 is a plan view taken along line D-D of FIG. 2. FIG. 7 is an enlarged view of region P of FIG. 2. FIG. 8 is a view for describing a planar shape of a semiconductor liner film in FIGS. 5 and 6.

For reference, FIG. 1 is simply illustrated except for a first gate insulating film 130, a source/drain etch stop film 185, interlayer insulating films 190 and 191, and a wiring structure 205.

Referring to FIGS. 1 to 8, a semiconductor device according to some example embodiments may include a first active pattern AP1, a plurality of first gate structures GS1, and a first source/drain pattern 150. The term “source/drain pattern” may refer to either a source pattern, a drain pattern, or both the source and drain patterns.

A substrate 100 may be bulk silicon or silicon-on-insulator (SOI). The substrate 100 may be a silicon substrate, and may include, for example, silicon germanium, silicon germanium on insulator (SGOI), indium antimonide, lead tellurium compound, indium arsenide, indium phosphide, gallium arsenide, or gallium antimonide, but is not limited thereto.

The first active pattern AP1 may be disposed on the substrate 100. The first active pattern AP1 may extend in a first direction D1 and may exhibit an elongated orientation along the first direction D1. As an example, the first active pattern API may be disposed in a region where a P-channel metal oxide semiconductor (PMOS) is formed. As another example, the first active pattern API may be disposed in a region where an N-channel metal oxide semiconductor (NMOS) is formed. The first active pattern AP1 may serve as a component for the fabrication of PMOS or NMOS. In the following description, the first active pattern AP1 will be described as being disposed in the region where the PMOS is formed.

The first active pattern API may be a multi-channel active pattern. The first active pattern AP1 may include a first lower pattern BP1 and a plurality of first sheet patterns NS1. The first lower pattern BP1 may protrude from the substrate 100. The first lower pattern BP1 may extend to be long in the first direction D1.

The plurality of first sheet patterns NS1 may be disposed on an upper surface BP1_US of the first lower pattern. The plurality of first sheet patterns NS1 may be spaced apart from the first lower pattern BP1 in a third direction D3. The respective first sheet patterns NS1 may be spaced apart from each other in the third direction D3.

The plurality of first sheet patterns NS1 may include an uppermost sheet pattern NS1_UM. The uppermost sheet pattern NS1_UM may be a sheet pattern farthest from the first lower pattern BP1 among the plurality of first sheet patterns NS1 in the third direction D3.

Each first sheet pattern NS1 may include an upper surface NS1_US and a bottom surface NS1_BS. The upper surface NS1_US of the first sheet pattern is a surface opposite to the bottom surface NS1_BS of the first sheet pattern in the third direction D3. Each first sheet pattern NS1 may include first sidewalls NS1_SW1 opposite to each other in the first direction D1 and second sidewalls NS1_SW2 opposite to each other in a second direction D2. The third direction D3 may be a direction intersecting the first direction D1 and the second direction D2. For example, the third direction D3 may be a thickness direction of the substrate 100. The first direction D1 may be a direction intersecting the second direction D2.

The upper surface NS1_US of the first sheet pattern and the bottom surface NS1_BS of the first sheet pattern may be connected by the first sidewall NS1_SW1 of the first sheet pattern and the second sidewall NS1_SW2 of the first sheet pattern. The first sidewall NS1_SW1 of the first sheet pattern is connected to and in contact with a first source/drain pattern 150 to be described later. The first sidewall NS1_SW1 of the first sheet pattern may include an end of the first sheet pattern NS1.

An upper surface AP1_US of the first active pattern may be an upper surface of a sheet pattern disposed on the uppermost portion among the plurality of first sheet patterns NS1. That is, an upper surface of the uppermost sheet pattern NS1_UM may be the upper surface AP1_US of the first active pattern. It is illustrated that three first sheet patterns NS1 are disposed in the third direction D3, but this is only for convenience of explanation, and the number of first sheet patterns NS1 is not limited thereto.

The first lower pattern BP1 may also be formed by etching a portion of the substrate 100 and may include an epitaxial layer grown from the substrate 100. The first lower pattern BP1 may include silicon or germanium, which is an elemental semiconductor material. In addition, the first lower pattern BP1 may include a compound semiconductor, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element.

The III-V compound semiconductor may be, for example, one of a binary compound, a ternary compound, or a quaternary compound formed by combining at least one of aluminum (Al), gallium (Ga), and indium (In), which are group III elements, and one of phosphorus (P), arsenic (As), and antimony (Sb), which are group V elements.

The first sheet pattern NS1 may include one of silicon or germanium, which is an elemental semiconductor material, a group IV-IV compound semiconductor, or a group III-V compound semiconductor. Each first sheet pattern NS1 may also include the same material as the first lower pattern BP1 or a material different from that of the first lower pattern BP1.

In the semiconductor device according to some example embodiments, the first lower pattern BP1 may be a silicon lower pattern containing silicon, and the first sheet pattern NS1 may be a silicon sheet pattern containing silicon.

A width of the first sheet pattern NS1 in the second direction D2 may increase or decrease in proportion to a width of the first lower pattern BP1 in the second direction D2. As an example, it is illustrated that the widths of the first sheet patterns NS1 stacked in the third direction D3 in the second direction D2 are the same, but this is only the convenience of explanation and the present disclosure is not limited thereto. Unlike illustrated, as a distance from the first lower pattern BP1 increases, the widths of the first sheet patterns NS1 stacked in the third direction D3 in the second direction D2 may decrease.

A field insulating film 105 may be disposed on the substrate 100 and sidewalls of the first lower pattern BP1. The field insulating film 105 is not disposed on the upper surface BP1_US of the first lower pattern.

As an example, the field insulating film 105 may entirely cover the sidewalls of the first lower pattern BP1. Unlike illustrated, the field insulating film 105 may cover portions of the sidewalls of the first lower pattern BP1. In this case, a portion of the first lower pattern BP1 may protrude more than an upper surface of the field insulating film 105 in the third direction D3.

Each of the first sheet patterns NS1 is disposed to be higher than the upper surface of the field insulating film 105. The field insulating film 105 may include, for example, an oxide film, a nitride film, an oxynitride film, or a combination thereof. It is illustrated that the field insulating film 105 is a single film, but this is merely for convenience of explanation, and the present disclosure is not limited thereto.

The plurality of first gate structures GS1 may be disposed on the substrate 100. Each of the first gate structures GS1 may extend in the second direction D2. The first gate structures GS1 may be disposed to be spaced apart from each other in the first direction D1. The first gate structures GS1 may be adjacent to each other in the first direction D1. For example, the first gate structures GS1 may be disposed on both sides of the first source/drain pattern 150 in the first direction D1.

The first gate structure GS1 may be disposed on the first active pattern AP1. The first gate structure GS1 may intersect both the first active pattern AP1 and the first lower pattern BP1. The first gate structure GS1 may surround each of the first sheet patterns NS1. The first gate structure GS1 may include, for example, a first gate electrode 120, a first gate insulating film 130, a first gate spacer 140, and a first gate capping pattern 145.

The first gate structure GS1 may include a plurality of inner gate structures INT1_GS1, INT2_GS1, and INT3_GS1 disposed between the first sheet patterns NS1 adjacent to each other in the third direction D3 and between the first lower pattern BP1 and the first sheet pattern NS1. The inner gate structures INT1_GS1, INT2_GS1, and INT3_GS1 may be disposed between the upper surface BP1_US of the first lower pattern and the bottom surface NS1_BS of the first sheet pattern, and between the upper surface NS1_US of the first sheet pattern and the bottom surface NS1_BS of the first sheet pattern facing each other in the third direction D3. The number of inner gate structures INT1_GS1, INT2_GS1, and INT3_GS1 may be the same as the number of first sheet patterns NS1.

The first inner gate structures INT1_GS1, INT2_GS1, and INT3_GS1 are in contact with the upper surface BP1_US of the first lower pattern, the upper surface NS1_US of the first sheet pattern, and the bottom surface NS1_BS of the first sheet pattern. The inner gate structures INT1_GS1, INT2_GS1, and INT3_GS1 may be in direct contact with a first source/drain pattern 150, which will be described later.

The first gate structure GS1 may include a first inner gate structure INT1_GS1, a second inner gate structure INT2_GS1, and a third inner gate structure INT3_GS1. The first inner gate structure INT1_GS1, the second inner gate structure INT2_GS1, and the third inner gate structure INT3_GS1 may be sequentially disposed on the first lower pattern BP1.

The third inner gate structure INT3_GS1 may be disposed between the first lower pattern BP1 and the first sheet pattern NS1. The third inner gate structure INT3_GS1 may be disposed at a lowermost portion among the inner gate structures INT1_GS1, INT2_GS1, and INT3_GS1. The third inner gate structure INT3_GS1 may be a lowermost inner gate structure.

The first inner gate structure INT1_GS1 and the second inner gate structure INT2_GS1 may be disposed between the first sheet patterns NS1 adjacent to each other in the third direction D3. The first inner gate structure INT1_GS1 may be disposed at an uppermost portion among the inner gate structures INT1_GS1, INT2_GS1, and INT3_GS1. The first inner gate structure INT1_GS1 may be in contact with the bottom surface NS1_US of the uppermost sheet pattern NS1_UM. The first inner gate structure INT1_GS1 may be an uppermost inner gate structure. The second inner gate structure INT2_GS1 is disposed between the first inner gate structure INT1_GS1 and the third inner gate structure INT3_GS1.

The inner gate structures INT1_GS1, INT2_GS1, and INT3_GS1 include a gate electrode 120 and a gate insulating film 130 disposed between the first sheet patterns NS1 adjacent to each other and between the first lower pattern BP1 and the first sheet pattern NS1.

For example, a width of the first inner gate structure INT1_GS1 in the first direction D1 may be the same as a width of the second inner gate structure INT2_GS1 in the first direction D1. A width of the third inner gate structure INT3_GS1 in the first direction D1 may be the same as the width of the second inner gate structure INT2_GS1 in the first direction D1.

As another example, the width of the third inner gate structure INT3_GS1 in the first direction D1 may be greater than the width of the second inner gate structure INT2_GS1 in the first direction D1. The width of the first inner gate structure INT1_GS1 in the first direction D1 may be the same as the width of the second inner gate structure INT2_GS1 in the first direction D1.

Taking the second inner gate structure INT2_GS1 as an example, the width of the second inner gate structure INT2_GS1 may be measured at the midpoint between the upper surface NS1_US of the first sheet pattern and the opposing bottom surface NS1_BS of the first sheet pattern, both aligned in the third direction D3.

For reference, a plan view at the level of the second inner gate structure INT2_GS1 is illustrated in FIG. 6. A plan view at the level of the first sheet pattern NS1 disposed at the center among the first sheet patterns NS1 is illustrated in FIG. 5. Although not illustrated, when a portion where a first source/drain contact 180 is formed is excluded, a plan view at the level of other inner gate structures INT1_GS1 and INT3_GS1 may also be similar to that of FIG. 6. Although not illustrated, when a portion where a first source/drain contact 180 is formed is excluded, a plan view at the level of other first sheet patterns NS1 may also be similar to that of FIG. 5.

The first gate electrode 120 may be disposed on the first lower pattern BP1. The first gate electrode 120 may intersect the first lower pattern BP1. The first gate electrode 120 may surround the first sheet pattern NS1. A portion of the first gate electrode 120 may be disposed between the first sheet patterns NS1 adjacent to each other and between the first lower pattern BP1 and the first sheet pattern NS1.

The first gate electrode 120 may include at least one of a metal, a metal alloy, conductive metal nitride, metal silicide, a doped semiconductor material, conductive metal oxide, and conductive metal oxynitride. The first gate electrode 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxide and the conductive metal oxynitride may include an oxidized form of the above-described materials, but are not limited thereto.

The gate electrode 120 may be disposed on both sides of a first source/drain pattern 150 to be described later. The first gate structures GS1 may be disposed on both sides of the first source/drain pattern 150 in the first direction D1.

As an example, all of the first gate electrodes 120 disposed on both sides of the first source/drain pattern 150 may be normal gate electrodes used as gates of the transistor. As another example, the gate electrode 120 disposed on one side of the first source/drain pattern 150 is used as the gate of the transistor, but the gate electrode 120 disposed on the other side of the first source/drain pattern 150 may be a dummy gate electrode.

The first gate insulating film 130 may extend along the upper surface of the field insulating film 105 and the upper surface BP1_US of the first lower pattern. The first gate insulating film 130 may surround the plurality of first sheet patterns NS1. The first gate insulating film 130 may be disposed along a circumference of the first sheet pattern NS1. The first gate electrode 120 is disposed on the first gate insulating film 130. The first gate insulating film 130 is disposed between the first gate electrode 120 and the first sheet pattern NS1. A portion of the first gate insulating film 130 may be disposed between the first sheet patterns NS1 adjacent to each other in the third direction D3 and between the first lower pattern BP1 and the first sheet pattern NS1.

The first gate insulating film 130 may include silicon oxide, silicon-germanium oxide, germanium oxide, silicon oxynitride, silicon nitride, or a high-k material having a dielectric constant greater than that of the silicon oxide. The high-k material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

It is illustrated that the first gate insulating film 130 is a single film, but it is only for convenience of explanation and the present disclosure is not limited thereto. The first gate insulating film 130 may include a plurality of film. The first gate insulating film 130 may also include an interfacial layer and a high-k insulating film disposed between the first sheet pattern NS1 and the first gate electrode 120, wherein k denotes a dielectric constant.

The semiconductor device according to some example embodiments may include a negative capacitance (NC) FET using a negative capacitor. For example, the first gate insulating film 130 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature by using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When aluminum (Al) is used as the dopant, the ferroelectric material film may include aluminum ranging from 3 to 8 atomic percentage (at %) of the total composition. Here, a dopant ratio may be defined as a ratio of aluminum to the sum of hafnium and aluminum.

When silicon (Si) is used as the dopant, the ferroelectric material film may include 2 to 10 at % of silicon. When yttrium (Y) is used as the dopant, the ferroelectric material film may include 2 to 10 at % of yttrium. When gadolinium (Gd) is used as the dopant, the ferroelectric material film may contain 1 to 7 at % of gadolinium. When zirconium (Zr) is used as the dopant, the ferroelectric material film may include 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, for example, at least one of hafnium oxide, zirconium oxide, and aluminum oxide, but is not limited thereto.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include the hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, for example, 0.5 to 10nm, but is not limited thereto. Since a critical thickness representing the ferroelectric characteristics may vary for each ferroelectric material, the thickness of the ferroelectric material film may vary depending on the ferroelectric material.

As an example, the first gate insulating film 130 may include one ferroelectric material film. As another example, the first gate insulating film 130 may include a plurality of ferroelectric material films spaced apart from each other. The first gate insulating film 130 may have a stacked layer structure in which a plurality of ferroelectric material films and a plurality of paraelectric material films are alternately stacked.

The first gate spacer 140 may be disposed on sidewalls 120SW of the first gate electrode. The first gate spacer 140 may not be disposed between the first lower pattern BP1 and the first sheet pattern NS1 and between the first sheet patterns NS1 adjacent to each other in the third direction D3.

The first gate spacer 140 may include a first spacer 141 and a second spacer 142. The second spacer 142 may be disposed on the first spacer 141. The first spacer 141 may be disposed between the first gate electrode 120 and the second spacer 142.

The first spacer 141 may be in contact with the first gate insulating film 130 and the second spacer 142. The first spacer 141 may be in contact with the upper surface AP1_US of the first active pattern. The first spacer 141 may be in contact with the second sidewall NS1_SW2 of the first sheet pattern.

The first spacer 141 may include an extending portion 141E and a first protruding portion 141P1. The extending portion 141E of the first spacer may extend in the second direction D2 along the sidewall 120SW of the first gate electrode.

The first protruding portion 141P1 of the first spacer may protrude in the first direction D1 from the extending portion 141E of the first spacer. The first protruding portion 141P1 of the first spacer may protrude toward the first gate electrode 120. The first protruding portion 141P1 of the first spacer may be in contact with the first gate insulating film 130.

In the cross-sectional views as illustrated in FIGS. 2 and 7, the first spacer 141 may have, for example, an “L” shape. In the plan views as illustrated in FIGS. 5 and 6, the first spacer 141 may have, for example, an “L” shape.

The second spacer 142 may not be in contact with the upper surface AP1_US of the first active pattern. The second spacer 142 may not be in contact with the second sidewall NS1_SW2 of the first sheet pattern.

The second spacer 142 may include an extending portion 142E and a protruding portion 142P. The extending portion 142E of the second spacer may extend in the second direction D2 along the sidewall 120SW of the first gate electrode.

The protruding portion 142P of the second spacer may protrude in the first direction D1 from the extending portion 142E of the second spacer. The protruding portion 142P of the second spacer may protrude in a direction away from the first gate electrode 120. In other words, the protruding portion 142P of the second spacer may protrude toward the first source/drain pattern 150.

The protruding portion 142P of the second spacer includes a first surface 142P_S1 and a second surface 142P_S2 opposite to each other. The second surface 142P_S2 of the protruding portion of the second spacer may face the first sheet pattern NS1. The second surface 142P_S2 of the protruding portion of the second spacer may face the upper surface AP1_US of the first active pattern. The second surface 142P_S2 of the protruding portion of the second spacer may face the second sidewall NS1_SW2 of the first sheet pattern.

In the cross-sectional views as illustrated in FIGS. 2 and 7, the second spacer 142 may have, for example, an “L” shape. In the plan views as illustrated in FIGS. 5 and 6, the second spacer 142 may have, for example, an “L” shape.

The first spacer 141 and the second spacer 142 may include different insulating materials. The second spacer 142 may include a material having an etching selectivity with respect to the first spacer 141. Each of the first spacer 141 and the second spacer 142 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), and silicon oxycarbide (SiOC).

The first gate capping pattern 145 may be disposed on the first gate electrode 120 and the first gate spacer 140. An upper surface of the first gate capping pattern 145 may be on the same plane as an upper surface of the first interlayer insulating film 190, but is not limited thereto. Unlike illustrated, the first gate capping pattern 145 may be disposed between the first gate spacers 140.

The first gate capping pattern 145 may include, for example, at least one of silicon nitride (SiN), silicon oxynitride (SiON), silicon carbonitride (SiCN), silicon oxycarbonitride (SiOCN), and a combination thereof. The first gate capping pattern 145 may include a material having an etching selectivity with respect to the first interlayer insulating film 190.

The first source/drain pattern 150 may be disposed on the first active pattern AP1. The first source/drain pattern 150 may be disposed on the first lower pattern BP1. The first source/drain pattern 150 may be connected to the first sheet pattern NS1.

The first source/drain pattern 150 may be disposed on a side surface of the first gate structure GS1. The first source/drain pattern 150 may be disposed between the first gate structures GS1 adjacent to each other in the first direction D1. For example, the first source/drain pattern 150 may be disposed on both sides of the first gate structure GS1. Unlike illustrated, the first source/drain pattern 150 may be disposed on one side of the first gate structure GS1 and may not be disposed on the other side of the first gate structure GS1.

The first source/drain pattern 150 may be included in a source/drain of a transistor using the second sheet pattern NS2 as a channel region.

The first source/drain pattern 150 may be disposed in a first source/drain recess 150R. The first source/drain recess 150R extends in the third direction D3. The first source/drain recess 150R may be disposed between the first gate structures GS1 adjacent to each other in the first direction D1.

A bottom surface of the first source/drain recess 150R is defined by the first lower pattern BP1. Sidewalls of the first source/drain recess 150R may be defined by the first sheet pattern NS1 and the inner gate structures INT1_GS1, INT2_GS1, and INT3_GS1. The inner gate structures INT1_GS1, INT2_GS1, and INT3_GS1 may define portions of the sidewalls of the first source/drain recess 150R.

The inner gate structures INT1_GS1, INT2_GS1, and INT3_GS1 may include upper surfaces facing the bottom surface NS1_BS of the first sheet pattern. The inner gate structures INT1_GS1, INT2_GS1, and INT3_GS1 include bottom surfaces facing the upper surface NS1_US of the first sheet pattern or the upper surface BP1_US of the first lower pattern. The inner gate structures INT1_GS1, INT2_GS1, and INT3_GS1 include sidewalls connecting the upper surfaces of the inner gate structures INT1_GS1, INT2_GS1, and INT3_GS1 and the bottom surfaces of the inner gate structures INT1_GS1, INT2_GS1, and INT3_GS1. The sidewalls of the inner gate structures INT1_GS1, INT2_GS1, and INT3_GS1 may define portions of the sidewalls of the first source/drain recess 150R.

Between the first sheet pattern NS1 disposed on the lowermost portion and the first lower pattern BP1, a boundary between the first gate insulating film 130 and the first lower pattern BP1 may be the upper surface BP1_US of the first lower pattern. The upper surface BP1_US of the first lower pattern may be a boundary between the third inner gate structure INT3_GS1 and the first lower pattern BP1.

The first source/drain pattern 150 may be in contact with the first sheet pattern NS1 and the first lower pattern BP1. The first source/drain pattern 150 may be in contact with the first gate spacer 140. The first gate insulating films 130 of the inner gate structures INT1_GS1, INT2_GS1, and INT3_GS1 may be in contact with the first source/drain pattern 150.

The first source/drain pattern 150 may include an epitaxial pattern. The first source/drain pattern 150 includes a semiconductor material. The first source/drain pattern 150 may include a semiconductor liner film 151 and a semiconductor filling film 152.

The semiconductor liner film 151 may be continuously formed along the first source/drain recess 150R. The semiconductor liner film 151 may be formed along the sidewalls of the first source/drain recess 150R and the bottom surface of the first source/drain recess 150R. The semiconductor liner film 151 formed along the first source/drain recess 150R defined by the first sheet pattern NS1 is directly connected to the semiconductor liner film 151 formed along the first source/drain recess 150R defined by the inner gate structures INT1_GS1, INT2_GS1, and INT3_GS1.

The semiconductor liner film 151 may be in contact with the first active pattern AP1 and the inner gate structures INT1_GS1, INT2_GS1, and INT3_GS1. The semiconductor liner film 151 is in contact with the first gate insulating film 130, the first sheet pattern NS1, and the first lower pattern BP1.

The semiconductor liner film 151 may be in contact with the first gate spacer 140, the first spacer 141, the second spacer 142, the protruding portion 142P of the second spacer, and the second surface 142P_S2 of the protruding portion of the second spacer.

Based on the upper surface BP1_US of the first lower pattern, an uppermost portion of the semiconductor liner film 151 is higher than the upper surface of the uppermost sheet pattern NS1_UM. In other words, a height from the upper surface BP1_US of the first lower pattern to the uppermost portion of the semiconductor liner film 151 is greater than a height from the upper surface BP1_US of the first lower pattern to the upper surface of the uppermost sheet pattern NS1_UM.

In FIGS. 2 and 7, the semiconductor liner film 151 may cover a portion of the upper surface AP1_US of the first active pattern. The semiconductor liner film 151 may cover a portion of the upper surface of the uppermost sheet pattern NS1_UM. A portion of the semiconductor liner film 151 may be recessed between the upper surface of the uppermost sheet pattern NS1_UM and the second surface 142P_S2 of the protruding portion of the second spacer. The semiconductor liner film 151 is in contact with a portion of the upper surface AP1_US of the first active pattern.

In FIGS. 5 and 6, the semiconductor liner film 151 may be inserted between the second spacer 142 and the first sheet pattern NS1. A portion of the semiconductor liner film 151 may be recessed between the protruding portion 142P of the second spacer and the first sheet pattern NS1. The semiconductor liner film 151 may cover a portion of the second sidewall NS1_SW2 of the first sheet pattern. The semiconductor liner film 151 may be in contact with a portion of the second sidewall NS1_SW2 of the first sheet pattern.

The semiconductor liner film 151 may include an outer side surface 151_OSW and an inner side surface 151_ISW. The outer side surface 151_OSW of the semiconductor liner film may be in contact with the first active pattern AP1 and the inner gate structures INT1_GS1, INT2_GS1, and INT3_GS1. The outer side surface 151_OSW of the semiconductor liner film is in contact with the first gate insulating film 130, the first sheet pattern NS1, and the first lower pattern BP1. The outer side surface 151_OSW of the semiconductor liner film is directly connected to the first sidewall NS1_SW1 of the first sheet pattern.

The inner side surface 151_ISW of the semiconductor liner film may be a surface opposite to the outer side surface 151_OSW of the semiconductor liner film. The inner side surface 151_ISW of the semiconductor liner film may be a surface facing the semiconductor filling film 152.

In the plan views as illustrated in FIGS. 5, 6, and 8, the semiconductor liner film 151 may include a central portion 151CP and a protruding portion 151PP. The protruding portion 151PP of the semiconductor liner film may be disposed on both sides of the central portion 151CP of the semiconductor liner film in the second direction D2. The protruding portion 151PP of the semiconductor liner film protrudes toward the first gate electrode 120 in the first direction D1.

The central portion 151CP of the semiconductor liner film may be a portion of the semiconductor liner film 151 overlapping the first sheet pattern NS1 in the first direction D1. In other words, the central portion 151CP of the semiconductor liner film may be a portion of the semiconductor liner film 151 in contact with the first sidewall NS1_SW1 of the first sheet pattern. The outer side surface 151_OSW of the semiconductor liner film is included in the central portion 151CP of the semiconductor liner film.

Since the protruding portion 151PP of the semiconductor liner film protrudes from the central portion 151CP of the semiconductor liner film in the second direction D2, the protruding portion 151PP of the semiconductor liner film may overlap the first spacer 141 in the first direction D1.

The protruding portion 151PP of the semiconductor liner film may include a first surface 151PP_S1 and a second surface 151PP_S2 opposite to each other in the second direction D2. The protruding portion 151PP of the semiconductor liner film may include a connection surface 151PP_CS of the protruding portion of the semiconductor liner film connecting the first surface 151PP_S1 of the protruding portion of the semiconductor liner film and the second surface 151PP_S2 of the protruding portion of the semiconductor liner film.

The connection surface 151PP_CS of the protruding portion of the semiconductor liner film may be in contact with the first spacer 141. The connection surface 151PP_CS of the protruding portion of the semiconductor liner film may have a convex shape.

The first surface 151PP_S1 of the protruding portion of the semiconductor liner film faces the second spacer 142. The first surface 151PP_S1 of the protruding portion of the semiconductor liner film may be in contact with the second spacer 142. The first surface 151PP_S1 of the protruding portion of the semiconductor liner film may be in contact with the second surface 142P_S2 of the protruding portion of the second spacer.

The second surface 151PP_S2 of the protruding portion of the semiconductor liner film faces the first sheet pattern NS1. The second surface 151PP_S2 of the protruding portion of the semiconductor liner film covers a portion of the second sidewall NS1_SW2 of the first sheet pattern. The second surface 151PP_S2 of the protruding portion of the semiconductor liner film is in contact with the second sidewall NS1_SW2 of the first sheet pattern. The second surface 151PP_S2 of the protruding portion of the semiconductor liner film is in contact with the first gate insulating film 130.

In a plan view, the second surface 151PP_S2 of the protruding portion of the semiconductor liner film in contact with the second sidewall NS1_SW2 of the first sheet pattern may be a straight line. The second surface 151PP_S2 of the protruding portion of the semiconductor liner film in contact with the first gate insulating film 130 may be a straight line. Unlike illustrated, the second surface 151PP_S2 of the protruding portion of the semiconductor liner film in contact with the first gate insulating film 130 may be a curved line.

A width W12 of the semiconductor liner film 151 in the second direction D2 is greater than a width of the first sheet pattern NS1 in the second direction D2. A width W13 of a contact surface where the semiconductor liner film 151 and the first gate insulating film 130 are in contact with each other in the second direction D2 is less than the width W12 of the semiconductor liner film 151 in the second direction D2.

The semiconductor liner film 151 may include, for example, silicon-germanium. The semiconductor liner film 151 may include a silicon-germanium film. The semiconductor liner film 151 may include doped p-type impurities. For example, the p-type impurity may include one of boron (B) and gallium (Ga), but is not limited thereto.

The semiconductor filling film 152 is disposed on the semiconductor liner film 151. The semiconductor filling film 152 may be in contact with the semiconductor liner film 151. In FIG. 2, the semiconductor filling film 152 may fill the remainder of the first source/drain recess 150R.

The semiconductor filling film 152 is disposed on the inner side surface 151_ISW of the semiconductor liner film. For example, an entirety of the inner side surface 151_ISW of the semiconductor liner film may be in contact with the semiconductor filling film 152.

The semiconductor filling film 152 may not be in contact with the first spacer 141. The semiconductor filling film 152 may be in contact with the second spacer 142.

The semiconductor filling film 152 may include, for example, silicon-germanium. The semiconductor filling film 152 may include a silicon-germanium film. The semiconductor filling film 152 may include doped p-type impurities. A fraction of germanium of the semiconductor liner film 151 is less than a fraction of germanium of the semiconductor filling film 152.

Although not illustrated, a semiconductor capping film may be further disposed on the semiconductor filling film 152. The semiconductor capping film may extend along an upper surface of the semiconductor filling film 152. As an example, the semiconductor capping film may include silicon. As another example, the semiconductor capping film may include silicon-germanium. In this case, a fraction of germanium of the semiconductor capping film is less than a fraction of germanium of the semiconductor filling film 152.

A source/drain etch stop film 185 may be disposed on the first source/drain pattern 150. The source/drain etch stop film 185 may extend along an outer sidewall of the first gate spacer 140. Although not illustrated, the source/drain etch stop film 185 may be disposed on the upper surface of the field insulating film 105. The source/drain etch stop film 185 may not extend along a sidewall of the first gate capping pattern 145. Unlike illustrated, the source/drain etch stop film 185 may extend along the sidewall of the first gate capping pattern 145.

The source/drain etch stop film 185 may be in contact with the second spacer 142. The second spacer 142 is disposed between the source/drain etch stop film 185 and the first spacer 141. The source/drain etch stop film 185 may extend along the extending portion 142E of the second spacer. For example, the source/drain etch stop film 185 may be in contact with the first surface 142P_S1 of the protruding portion of the second spacer.

The source/drain etch stop film 185 may include a material having an etching selectivity with respect to a first interlayer insulating film 190, which will be described later. The source/drain etch stop film 185 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and a combination thereof.

A first interlayer insulating film 190 may be disposed on the source/drain etch stop film 185 and the first source/drain pattern 150. The first interlayer insulating film 190 may not cover the upper surface of the first gate capping pattern 145. For example, an upper surface of the first interlayer insulating film 190 may be on the same plane as the upper surface of the first gate capping pattern 145.

The first interlayer insulating film 190 may include, for example, at least one of silicon oxide, silicon nitride, silicon oxynitride, and a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SILK, amorphous fluorinated carbon, silica aerogels, silica xerogels, mesoporous silica, or a combination thereof, but is not limited thereto.

The first source/drain contact 180 is disposed on the first source/drain pattern 150. The first source/drain contact 180 is connected to the first source/drain pattern 150. The source/drain contact 180 may pass through the first interlayer insulating film 190 and the source/drain etch stop film 185 and be connected to the first source/drain pattern 150.

In the cross-sectional view as illustrated in FIG. 2, it is illustrated that the first source/drain contact 180 is not in contact with the first gate structure GS1, but the first source/drain contact 180 is not limited thereto. Unlike illustrated, the first source/drain contact 180 may be in contact with the first gate capping pattern 145.

A first contact silicide film 155 may be further disposed between the first source/drain contact 180 and the first source/drain pattern 150.

It is illustrated that the source/drain contact 180 is a single film, but this is only for convenience of explanation and the present disclosure is not limited thereto. The first source/drain contact 180 may include, for example, at least one of a metal, conductive metal nitride, conductive metal carbide, conductive metal oxide, conductive metal carbonitride, and a two-dimensional (2D) material. The first contact silicide film 155 may include metal silicide.

A second interlayer insulating film 191 may be disposed on the first interlayer insulating film 190. The second interlayer insulating film 191 may include, for example, at least one of silicon oxide, silicon nitride, silicon oxynitride, and a low-k material.

The wiring structure 205 is disposed in the second interlayer insulating film 191. The wiring structure 205 may be connected to the first source/drain contact 180. The wiring structure 205 may include a wiring line 207 and a wiring via 206.

It is illustrated that the wiring line 207 and the wiring via 206 are separated from each other, but this is only for convenience of explanation, and the present disclosure is not limited thereto. That is, as an example, after the wiring via 206 is formed, the wiring line 207 may be formed. As another example, the wiring via 206 and the wiring line 207 may be formed at the same time.

It is illustrated that each of the wiring line 207 and the wiring via 206 is a single film, but this is only for convenience of explanation, and the present disclosure is not limited thereto. Each of the wiring line 207 and the wiring via 206 may include, for example, at least one of a metal, conductive metal nitride, conductive metal carbide, conductive metal oxide, conductive metal carbonitride, and a two-dimensional (2D) material.

For example, an upper surface of the first source/drain contact 180 at a portion connected to the wiring structure 205 may be on the same plane as an upper surface of the first source/drain contact 180 at a portion not connected to the wiring structure 205.

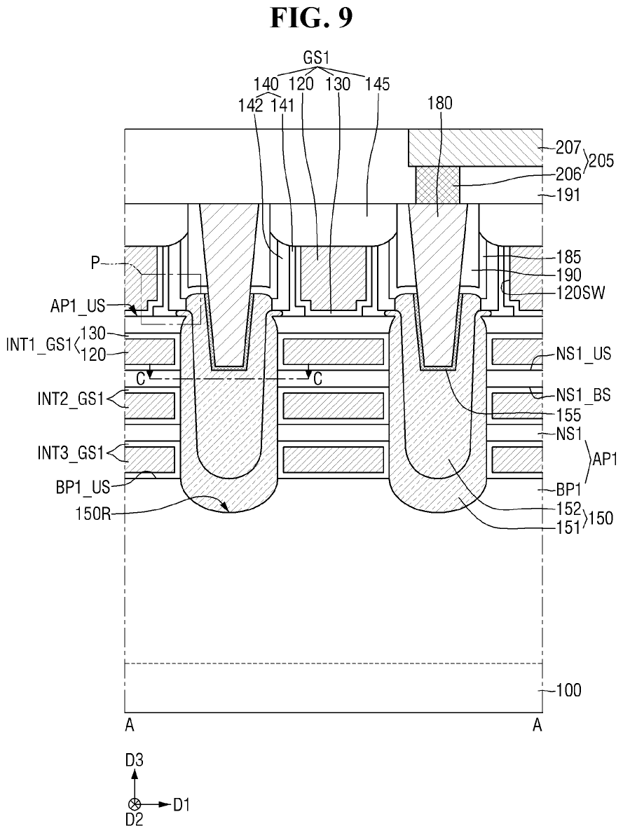

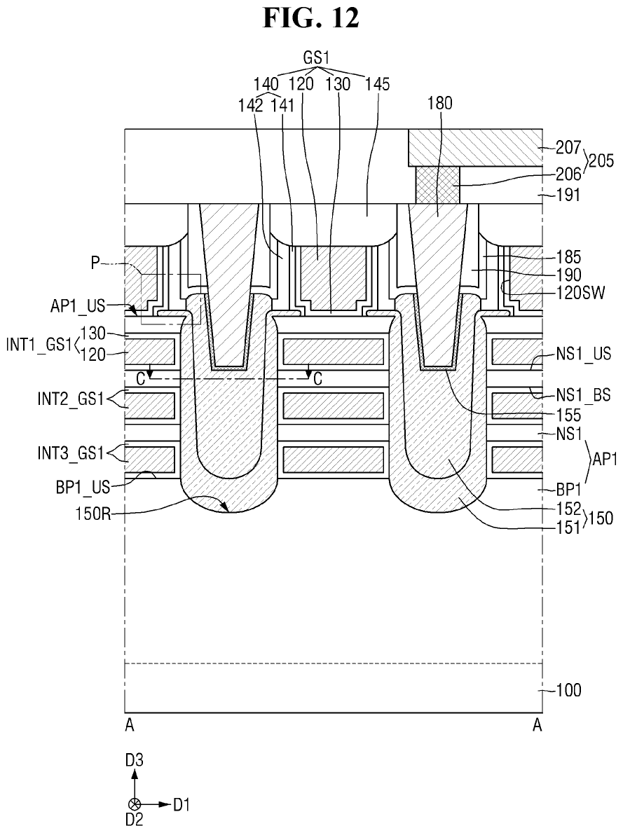

FIGS. 9 to 11 are views for describing a semiconductor device according to some example embodiments. FIGS. 12 to 16 are views for describing a semiconductor device according to some example embodiments. For convenience of explanation, points different from those described with reference to FIGS. 1 to 8 will be mainly described.

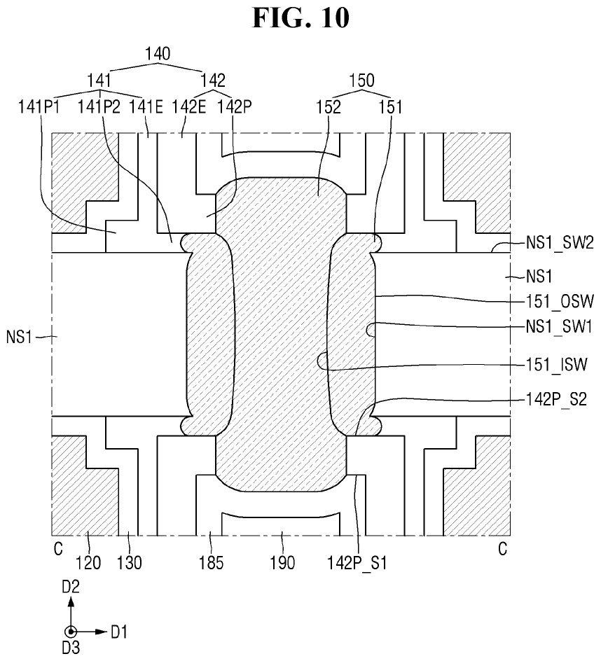

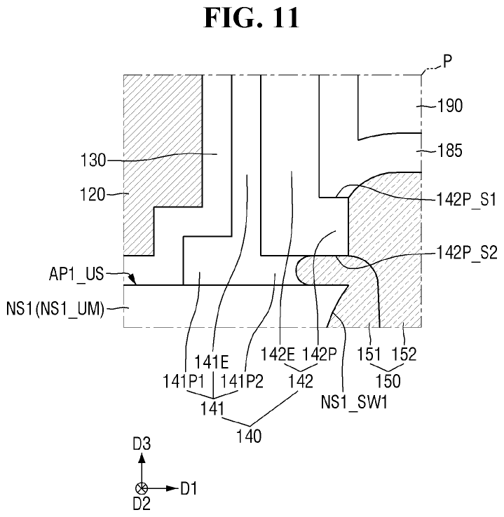

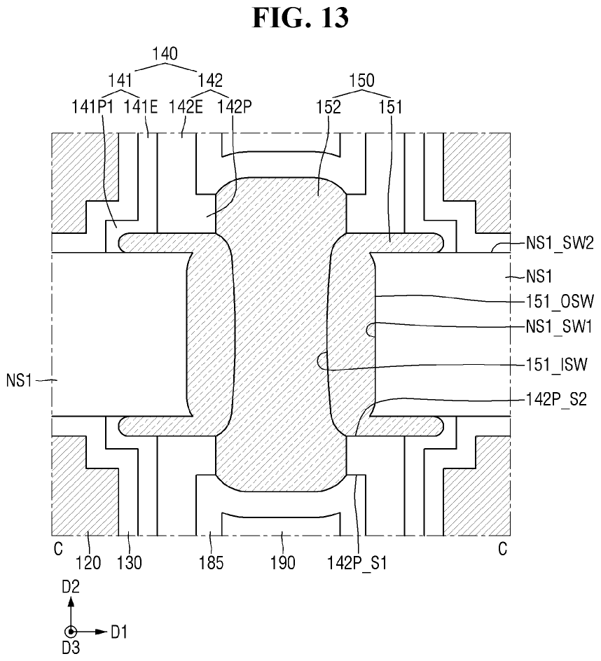

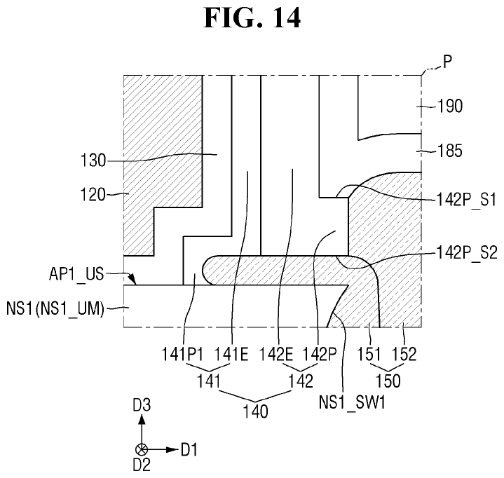

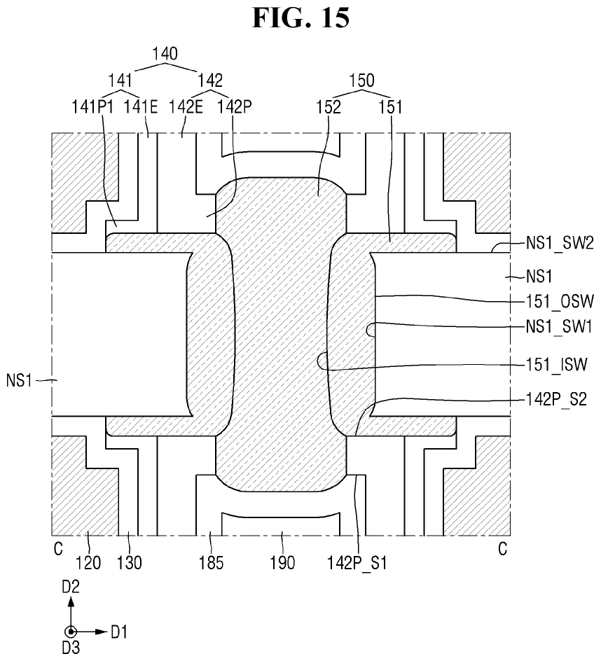

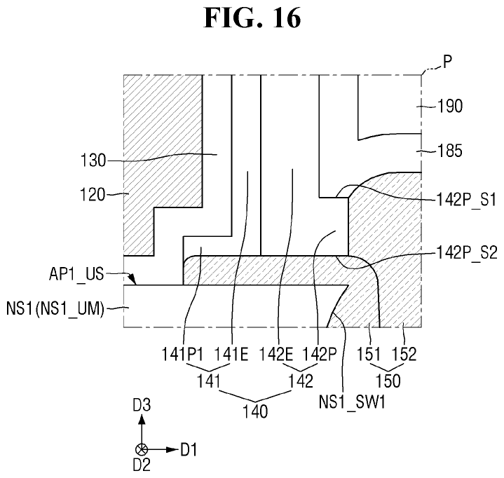

For reference, FIG. 10 is a plan view taken along line C-C of FIG. 9, and FIGS. 13 and 15 are plan views taken along line C-C of FIG. 12. FIG. 11 is an enlarged view of region P of FIG. 9, and FIGS. 14 and 16 are enlarged views of region P of FIG. 12. In a plan view at the level of the second inner gate structure INT2_GS1, a shape between the first source/drain pattern 150 and the first gate spacer 140 may be similar to that illustrated in FIGS. 10, 13, and 15.

Referring to FIGS. 9 to 11, in the semiconductor device according to some example embodiments, the first spacer 141 may further include a second protruding portion 141P2.

The second protruding portion 141P2 of the first spacer may protrude in the first direction D1 from the extending portion 141E of the first spacer toward the first source/drain pattern 150. The second protruding portion 141P2 of the first spacer may protrude in an opposite direction to the first protruding portion 141P1 of the first spacer.

In a cross-sectional view, the first spacer 141 may have, for example, a “T” shape rotated by 180 degrees. In a plan view, the first spacer 141 may have, for example, a “T” shape.

In a plan view, the semiconductor liner film 151 may not overlap the extending portion 141E of the first spacer in the second direction D2. The protruding portion (151PP in FIG. 8) of the semiconductor liner film may not protrude to the extending portion 141E of the first spacer.

For example, a thickness of the first protruding portion 141P1 of the first spacer may be greater than a thickness of the second protruding portion 141P2 of the first spacer. Unlike illustrated, the thickness of the first protruding portion 141P1 of the first spacer may be the same as the thickness of the second protruding portion 141P2 of the first spacer.

Referring to FIGS. 12 to 16, in the semiconductor device according to some example embodiments, in a plan view, the semiconductor liner film 151 may overlap the first protruding portion 141P1 of the first spacer in the second direction D2.

In addition, in a cross-section view, the semiconductor liner film 151 may overlap the first protruding portion 141P1 of the first spacer in the third direction D3. A portion of the semiconductor liner film 151 may be disposed between the first protruding portion 141P1 of the first spacer and the first sheet pattern NS1.

In FIGS. 13 and 14, the semiconductor liner film 151 may not extend to the first gate insulating film 130. The first protruding portion 141P1 of the first spacer may be in contact with the upper surface AP1_US of the first active pattern and the second sidewall NS1_SW2 of the first sheet pattern.

In FIGS. 15 and 16, the semiconductor liner film 151 may extend to the first gate insulating film 130. On the upper surface AP1_US of the first active pattern, the semiconductor liner film 151 may be in contact with the first gate insulating film 130. On the second sidewall NS1_SW2 of the first sheet pattern, the semiconductor liner film 151 may be in contact with the first gate insulating film 130.

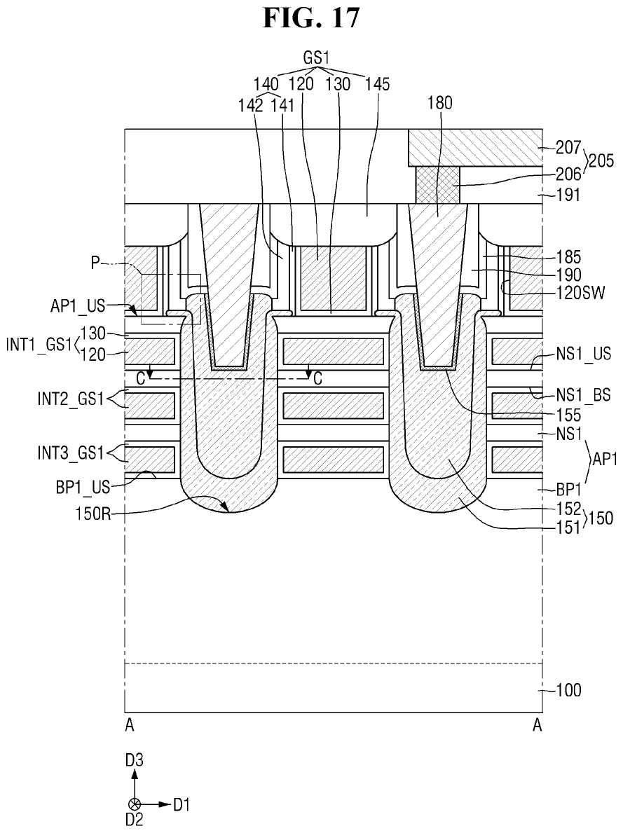

FIGS. 17 to 19 are views for describing a semiconductor device according to some example embodiments. For convenience of explanation, points different from those described with reference to FIGS. 1 to 8 will be mainly described.

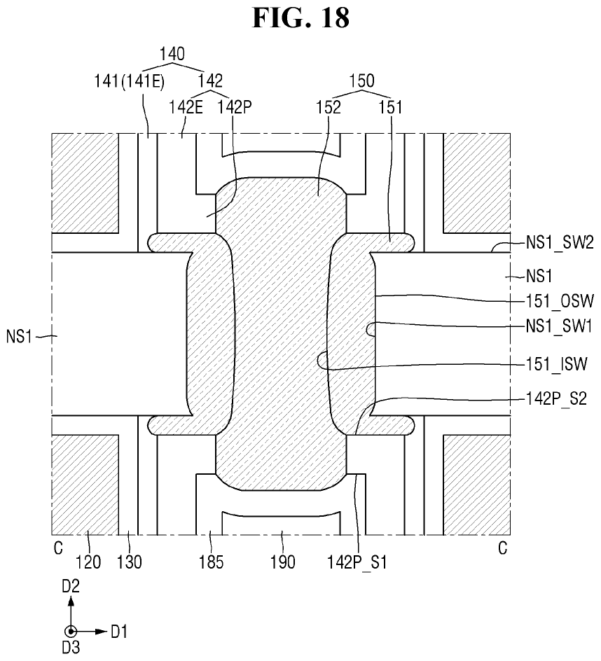

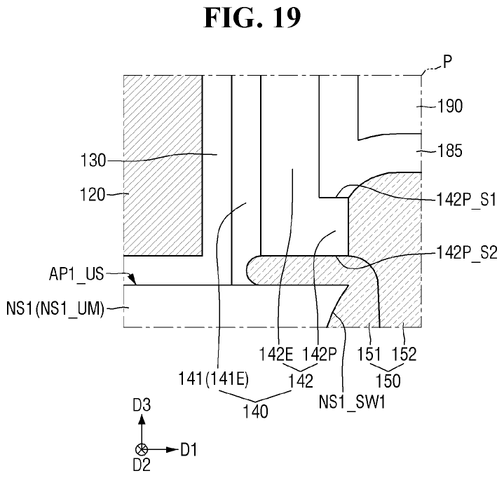

For reference, FIG. 18 is a plan view taken along line C-C of FIG. 17, and FIG. 19 is an enlarged view of region P of FIG. 17. In a plan view at the level of the second inner gate structure INT2_GS1, a shape between the first source/drain pattern 150 and the first gate spacer 140 may be similar to that illustrated in FIG. 18.

Referring to FIGS. 17 to 19, in the semiconductor device according to some example embodiments, the first spacer 141 may not include the first protruding portion (141P1 in FIG. 7).

For example, the first spacer 141 may include only the extending portion 141E of the first spacer.

In a cross-sectional view, the first spacer 141 may have, for example, an “I” shape. In a plan view, the first spacer 141 may have, for example, an “I” shape.

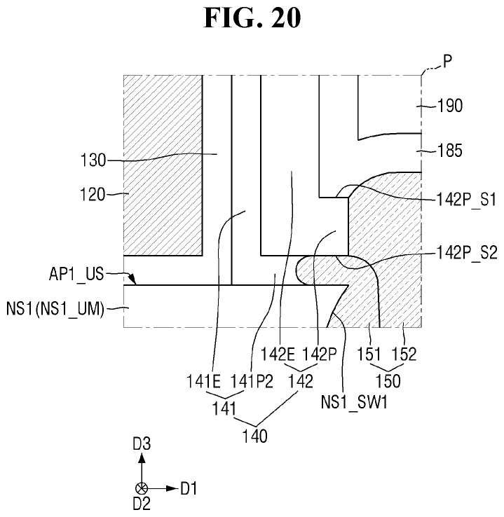

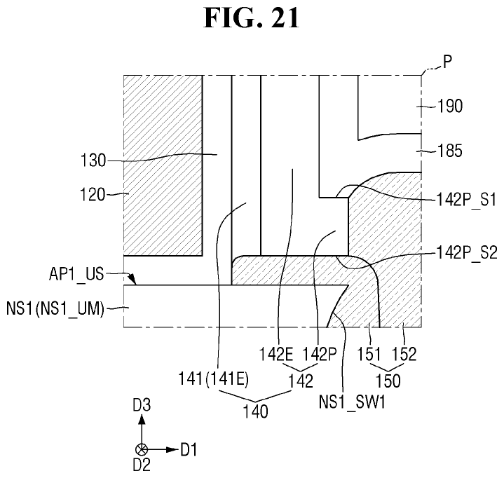

FIGS. 20 and 21 are views for describing a semiconductor device according to some example embodiments, respectively. For convenience of explanation, points different from those described with reference to FIGS. 17 to 19 will be mainly described. For reference, FIGS. 20 and 21 are enlarged views of region P of FIG. 17.

Referring to FIG. 20, in the semiconductor device according to some example embodiments, the first spacer 141 may further include a second protruding portion 141P2.

The second protruding portion 141P2 of the first spacer may protrude toward the first source/drain pattern 150. In a cross-sectional view, the first spacer 141 may have, for example, an “L” shape. In a plan view, the first spacer 141 may have, for example, an “L” shape.

Referring to FIG. 21, in the semiconductor device according to some example embodiments, the first spacer 141 may be disposed on the semiconductor liner film 151.

The first spacer 141 may not be in contact with the upper surface AP1_US of the first active pattern and the second sidewall (NS1_SW2 in FIG. 5) of the first sheet pattern. On the upper surface AP1_US of the first active pattern, the semiconductor liner film 151 may be in contact with the first gate insulating film 130. On the second sidewall NS1_SW2 of the first sheet pattern, the semiconductor liner film 151 may be in contact with the first gate insulating film 130.

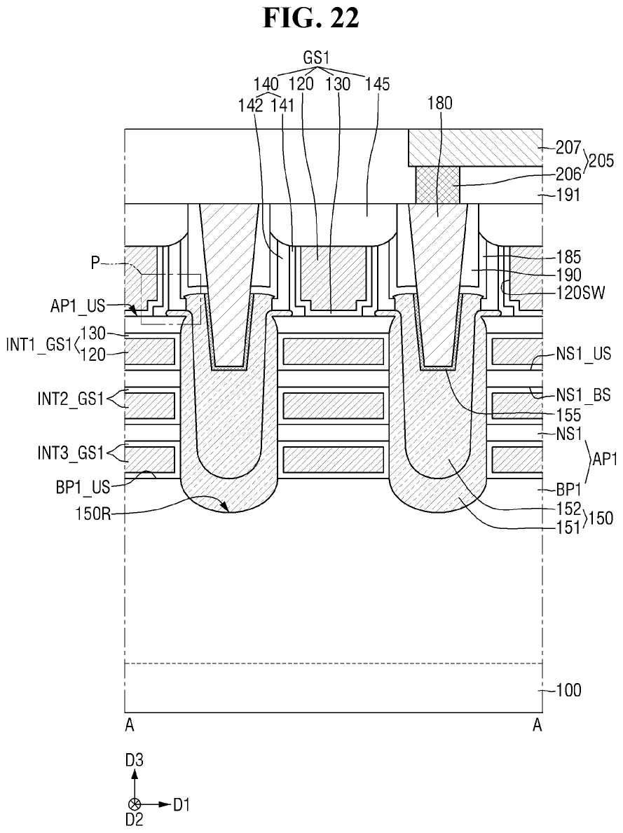

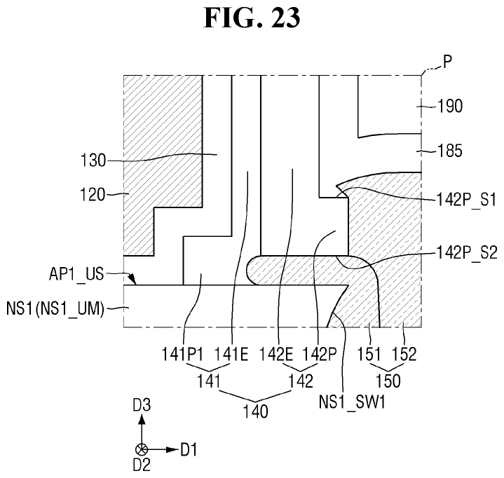

FIGS. 22 to 25 are views for describing a semiconductor device according to some example embodiments. For convenience of explanation, points different from those described with reference to FIGS. 1 to 8 will be mainly described. For reference, FIGS. 23 to 25 are enlarged views of region P of FIG. 22.

Referring to FIGS. 22 to 25, in the semiconductor device according to some example embodiments, a portion of the semiconductor filling film 152 may protrude more than the first surface 142P_S1 of the protruding portion of the second spacer in the third direction D3.

A portion of the semiconductor filling film 152 may be disposed on the first surface 142P_S1 of the protruding portion of the second spacer. A portion of the semiconductor filling film 152 may overlap the first surface 142P_S1 of the protruding portion of the second spacer in the third direction D3.

In FIG. 23, the semiconductor filling film 152 may not be in contact with the first surface 142P_S1 of the protruding portion of the second spacer. The semiconductor filling film 152 may not be in contact with the extending portion 142E of the second spacer.

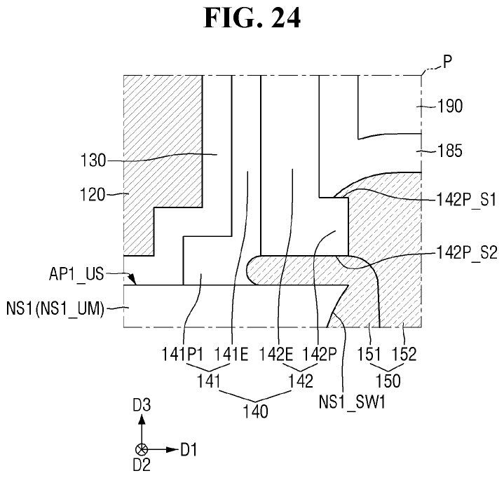

In FIG. 24, the semiconductor filling film 152 may be in contact with the first surface 142P_S1 of the protruding portion of the second spacer. The semiconductor filling film 152 may not be in contact with the extending portion 142E of the second spacer. Unlike illustrated, the semiconductor filling film 152 may be in contact with the extending portion 142E of the second spacer.

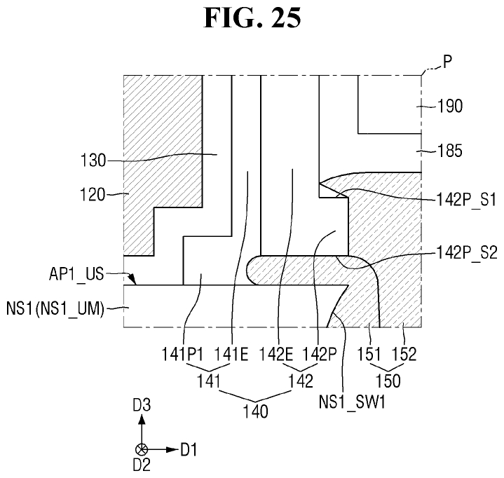

In FIG. 25, the semiconductor filling film 152 may be in contact with the extending portion 142E of the second spacer. The semiconductor filling film 152 may not be in contact with the first surface 142P_S1 of the protruding portion of the second spacer.

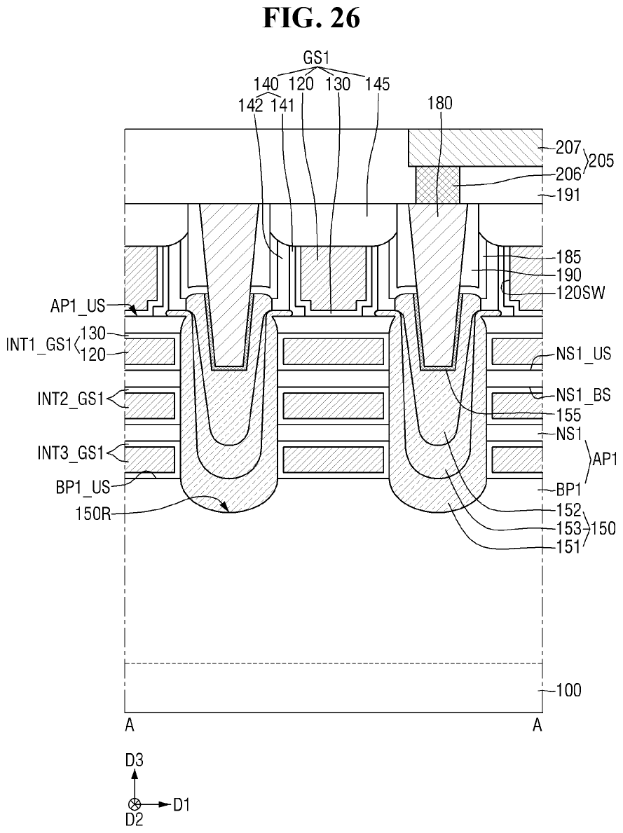

FIGS. 26 to 30 are views for describing a semiconductor device according to some example embodiments. For convenience of explanation, points different from those described with reference to FIGS. 1 to 8 will be mainly described.

Referring to FIG. 26, in the semiconductor device according to some example embodiments, the first source/drain pattern 150 may further include a semiconductor insertion film 153 disposed between the semiconductor liner film 151 and the semiconductor filling film 152.

The semiconductor insertion film 153 is disposed on the semiconductor liner film 151. The semiconductor insertion film 153 may include silicon-germanium, a silicon-germanium film, and/or doped p-type impurities.

A fraction of germanium of the semiconductor insertion film 153 is less than a fraction of germanium of the semiconductor filling film 152. As an example, the fraction of germanium of the semiconductor insertion film 153 is greater than a fraction of germanium of the semiconductor liner film 151. As another example, the fraction of germanium of the semiconductor insertion film 153 is less than the fraction of germanium of the semiconductor liner film 151.

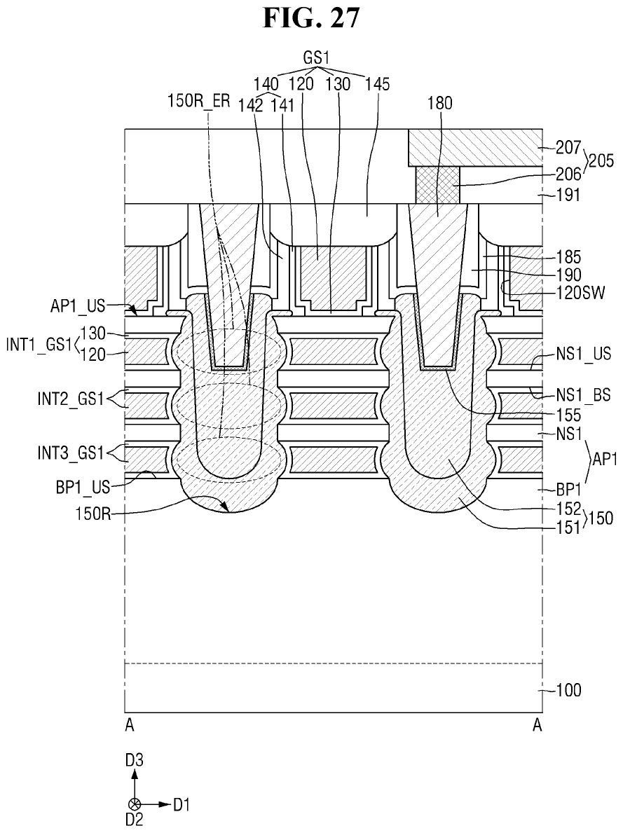

Referring to FIG. 27, in the semiconductor device according to some example embodiments, the first source/drain recess 150R may include a plurality of width extension regions 150R_ER.

The width extension region 150R_ER of the first source/drain recess may be defined between the first sheet patterns NS1 adjacent to each other in the third direction D3. The width extension region 150R_ER of the first source/drain recess may be defined between the first lower pattern BP1 and the first sheet pattern NS1. The width extension region 150R_ER of the first source/drain recess may extend between the first sheet patterns NS1 adjacent to each other in the third direction D3. The width extension region 150R_ER of the first source/drain recess may be defined between the inner gate structure INT1_GS1, INT2_GS1, and INT3_GS1 adjacent to each other in the first direction D1.

As a distance from the upper surface BP1_US of the first lower pattern increases, each width extension region 150R_ER of the first source/drain recess may include a portion where a width thereof in the first direction D1 increases and a portion where a width thereof in the first direction D1 decreases. For example, as the distance from the upper surface BP1_US of the first lower pattern increases, the width of the width extension region 150R_ER of the first source/drain recess may increase and then decrease.

In each width extension region 150R_ER of the first source/drain recess, a point where the width of the width extension region 150R_ER of the first source/drain recess reaches its maximum is positioned either between the first sheet pattern NS1 and the first lower pattern BP1 or between the first sheet patterns NS1 adjacent to each other in the third direction D3.

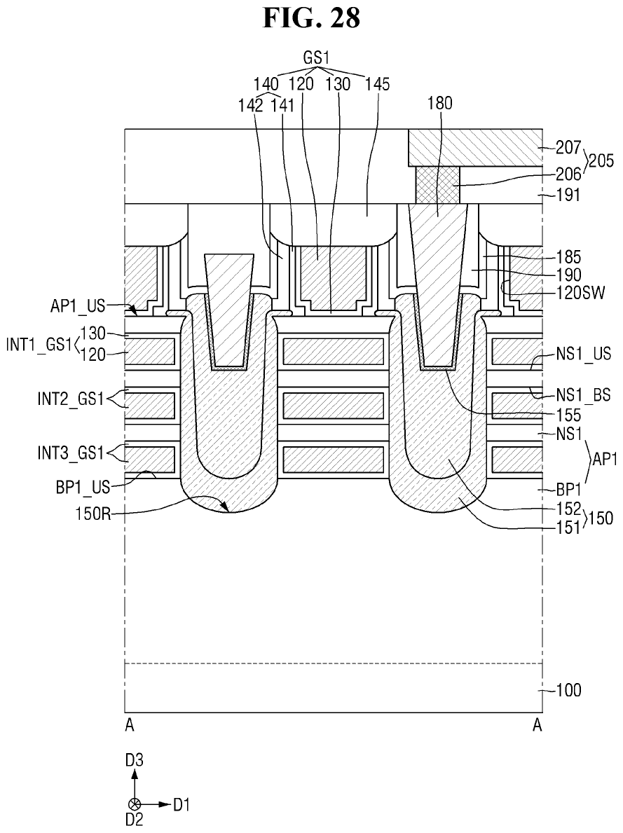

Referring to FIG. 28, in the semiconductor device according to some example embodiments, an upper surface of the first source/drain contact 180 at a portion not connected to the wiring structure 205 is lower than the upper surface of the first gate capping pattern 145.

An upper surface of the first source/drain contact 180 at a portion connected to the wiring structure 205 is higher than the upper surface of the first source/drain contact 180 at the portion not connected to the wiring structure 205.

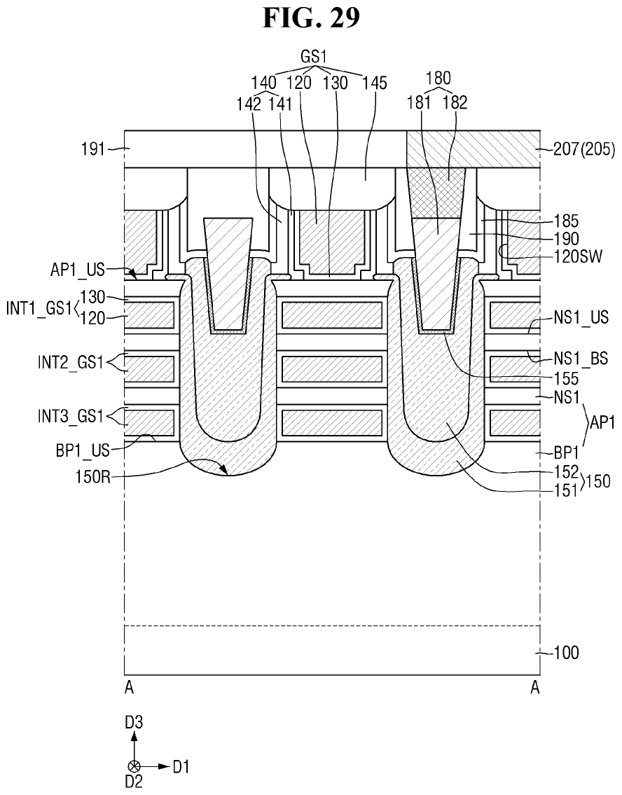

Referring to FIG. 29, in the semiconductor device according to some example embodiments, the first source/drain contact 180 includes a lower source/drain contact 181 and an upper source/drain contact 182.

The upper source/drain contact 182 may be disposed at the portion connected to the wiring structure 205. On the other hand, the upper source/drain contact 182 may not be disposed at the portion not connected to the wiring structure 205.

The wiring line 207 may be connected to the first source/drain contact 180 without the wiring via (206 in FIG. 2). The wiring structure 205 may not include the wiring via (206 in FIG. 2).

It is illustrated that each of the lower source/drain contact 181 and the upper source/drain contact 182 is a single film, but this is only for convenience of explanation and the present disclosure is not limited thereto. Each of the lower source/drain contact 181 and the upper source/drain contact 182 may include, for example, at least one of a metal, conductive metal nitride, conductive metal carbide, conductive metal oxide, conductive metal carbonitride, and a two-dimensional (2D) material.

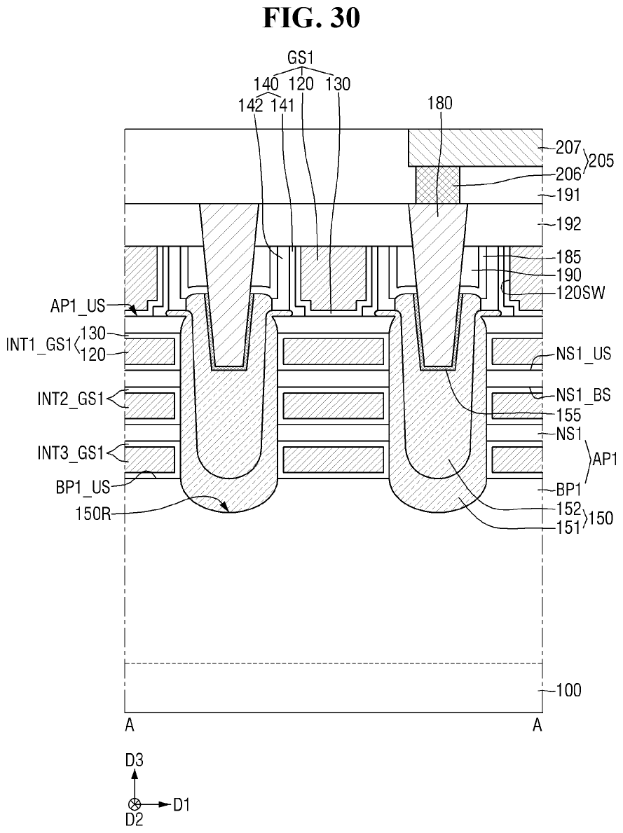

Referring to FIG. 30, in the semiconductor device according to some example embodiments, the first gate structure GS1 may not include the first gate capping pattern 145.

A third interlayer insulating film 192 may be disposed between the first interlayer insulating film 190 and the second interlayer insulating film 191. The third interlayer insulating film 192 may be disposed on the first gate structure GS1. The third interlayer insulating film 192 may cover the upper surface of the first gate electrode 120.

The third interlayer insulating film 192 may include, for example, at least one of silicon oxide, silicon nitride, silicon oxynitride, and a low-k material. It is illustrated that the third interlayer insulating film 192 is a single film, but the present disclosure is not limited thereto. Unlike illustrated, the third interlayer insulating film 192 may include a multilayer insulating film sequentially stacked on the first interlayer insulating film 190.

An upper surface of the first source/drain contact 180 may protrude more than the first gate structure GS1 in the third direction D3. A portion of the first source/drain contact 180 may be disposed in the third interlayer insulating film 192.

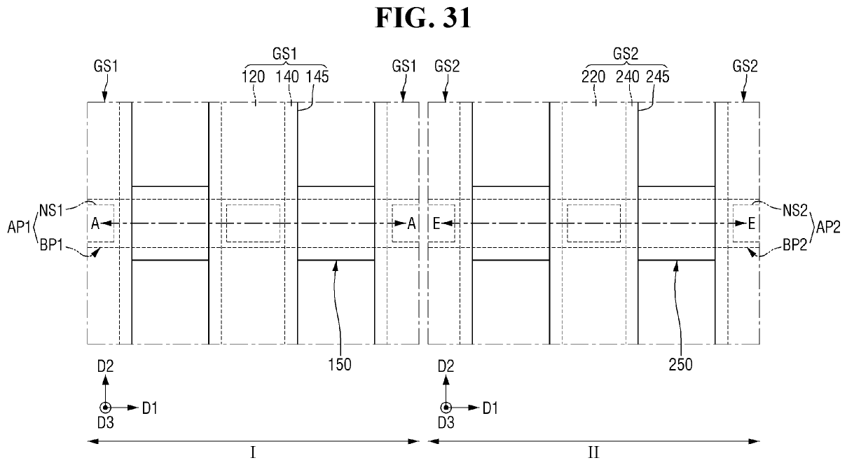

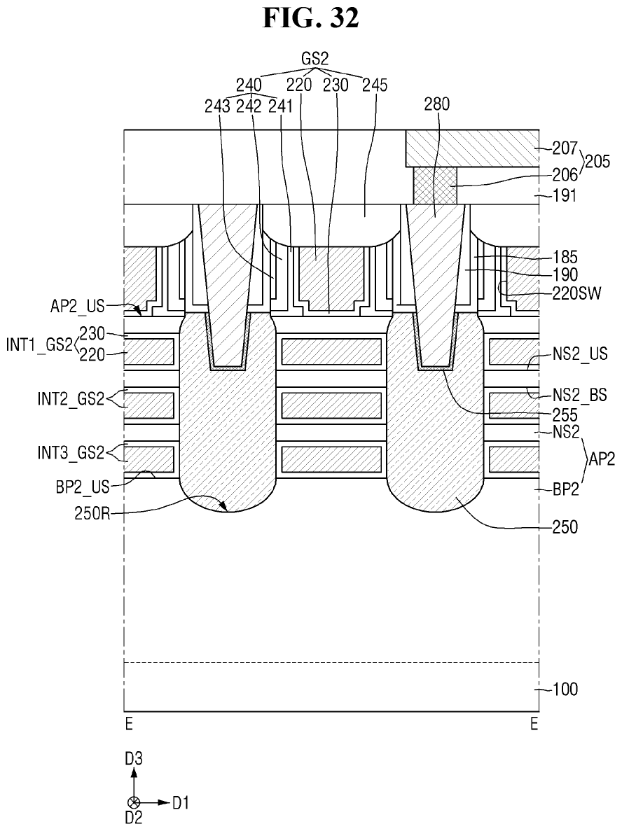

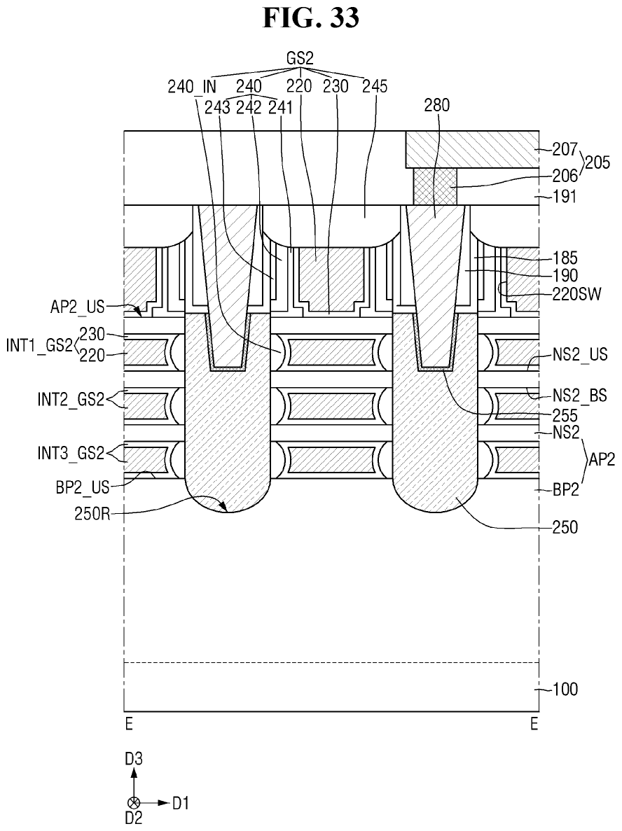

FIGS. 31 to 33 are views for describing a semiconductor device according to some example embodiments. For reference, FIG. 31 is an example plan view for describing a semiconductor device according to some example embodiments. FIGS. 32 and 33 are cross-sectional views taken along line E-E of FIG. 31.

In addition, a cross-sectional view taken along line A-A of FIG. 31 may be the same as one of FIGS. 2, 9, 12, 17, 22, 26, and 27. Additionally, a description of a first region I of FIG. 31 may be substantially the same as that described with reference to FIGS. 1 to 27. Accordingly, hereinafter, the contents of a second region II of FIG. 31 will be mainly described.

Referring to FIGS. 31 to 33, a semiconductor device according to some example embodiments may include a first active pattern AP1, a plurality of first gate structures GS1, a first source/drain pattern 150, a second active pattern AP2, a plurality of second gate structures GS2, and a second source/drain pattern 250.

The substrate 100 may include a first region I and a second region II. The first region I may be a region where a PMOS is formed, and the second region II may be a region where an NMOS is formed.

The first active pattern AP1, the plurality of first gate structures GS1, and the first source/drain pattern 150 are disposed in the first region I of the substrate 100. The second active pattern AP2, the plurality of second gate structures GS2, and the second source/drain pattern 250 are disposed in the second region II of the substrate 100.

The second active pattern AP2 may include a second lower pattern BP2 and a plurality of second sheet patterns NS2. The plurality of second sheet patterns NS2 may be disposed on an upper surface BP2_US of the second lower pattern. The second sheet pattern NS2 includes an upper surface NS2_US and a bottom surface NS2_BS that face each other in the third direction D3. An upper surface AP2_US of the second active pattern may be an upper surface of a sheet pattern disposed on the uppermost portion among the plurality of second sheet patterns NS2. Each of the second lower pattern BP2 and the second sheet pattern NS2 may include one of silicon or germanium, which is an elemental semiconductor material, a group IV-IV compound semiconductor, or a group III-V compound semiconductor. In the semiconductor device according to some example embodiments, the second lower pattern BP2 may be a silicon lower pattern containing silicon, and the second sheet pattern NS2 may be a silicon sheet pattern containing silicon.

A plurality of second gate structures GS2 may be disposed on the substrate 100. The second gate structure GS2 may be disposed on the second active pattern AP2. The second gate structure GS2 may intersect the second active pattern AP2. The second gate structure GS2 may intersect the second lower pattern BP2. The second gate structure GS2 may surround each second sheet pattern NS2. The second gate structure GS2 may include a plurality of inner gate structures INT1_GS2, INT2_GS2, and INT3_GS2 disposed between the second sheet patterns NS2 adjacent to each other in the third direction D3 and between the second lower pattern BP2 and the second sheet pattern NS2. The second gate structure GS2 may include, for example, a second gate electrode 220, a second gate insulating film 230, a second gate spacer 240, and a second gate capping pattern 245.

The second gate spacer 240 may be disposed on sidewalls 220SW of the second gate electrode. The second gate spacer 240 may include a third spacer 241, a fourth spacer 242, and a fifth spacer 243. The fourth spacer 242 may be disposed on the third spacer 241. The fourth spacer 242 may be disposed between the third spacer 241 and the fifth spacer 243.

In the cross-sectional views as illustrated in FIGS. 32 and 33, the third spacer 241 may have, for example, a “T” shape. The fourth spacer 242 may have, for example, an “L” shape. The fifth spacer 243 may have, for example, an “I” shape.

In FIG. 32, the second gate spacer 240 is not disposed between the plurality of inner gate structures INT1_GS2, INT2_GS2, and INT3_GS2 and the second source/drain pattern 250. The second gate insulating films 230 of the inner gate structures INT1_GS2, INT2_GS2, and INT3_GS2 may be in contact with the second source/drain pattern 250.

In FIG. 33, the second gate structure GS2 may include an inner spacer 240_IN. The inner spacer 240_IN may be disposed between the second sheet patterns NS2 adjacent to each other in the third direction D3 and between the second lower pattern BP2 and the second sheet pattern NS2. The inner spacer 240_IN may be in contact with the second gate insulating films 230 included in the inner gate structures INT1_GS2, INT2_GS2, and INT3_GS2. The inner spacer 240_IN may define a portion of the second source/drain recess 250R.

The second source/drain pattern 250 may be disposed on the second active pattern AP2. The second source/drain pattern 250 may be formed on the second lower pattern BP2. The second source/drain pattern 250 may be connected to the second sheet pattern NS2. The second source/drain pattern 250 may be included in a source/drain of a transistor using the second sheet pattern NS2 as a channel region.

The second source/drain pattern 250 may be disposed in a second source/drain recess 250R. A bottom surface of the second source/drain recess 250R is defined by the second lower pattern BP2. Sidewalls of the second source/drain recess 250R may be defined by the second sheet pattern NS2 and the second gate structure GS2.

The second source/drain pattern 250 may include an epitaxial pattern. The second source/drain pattern 250 may include silicon or germanium, which is, for example, an elemental semiconductor material. In addition, the second source/drain pattern 250 may include, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element. For example, the second source/drain pattern 250 may include silicon, silicon-germanium, silicon carbide, or the like, but is not limited thereto.

The second source/drain pattern 250 may include impurities doped in a semiconductor material. For example, the second source/drain pattern 250 may include n-type impurities. The doped impurities may include at least one of phosphorus (P), arsenic (As), antimony (Sb), and bismuth (Bi).

Unlike illustrated, the second source/drain recess 250R may include a plurality of width extension regions, like the first source/drain recess 150R illustrated in FIG. 27.

The second source/drain contact 280 is disposed on the second source/drain pattern 250. The second source/drain contact 280 is connected to the second source/drain pattern 250. A second contact silicide film 255 may be further disposed between the second source/drain contact 280 and the second source/drain pattern 250.

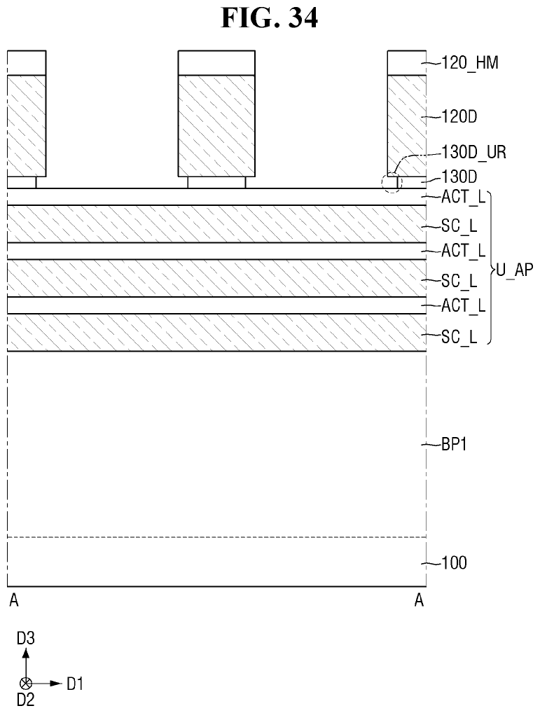

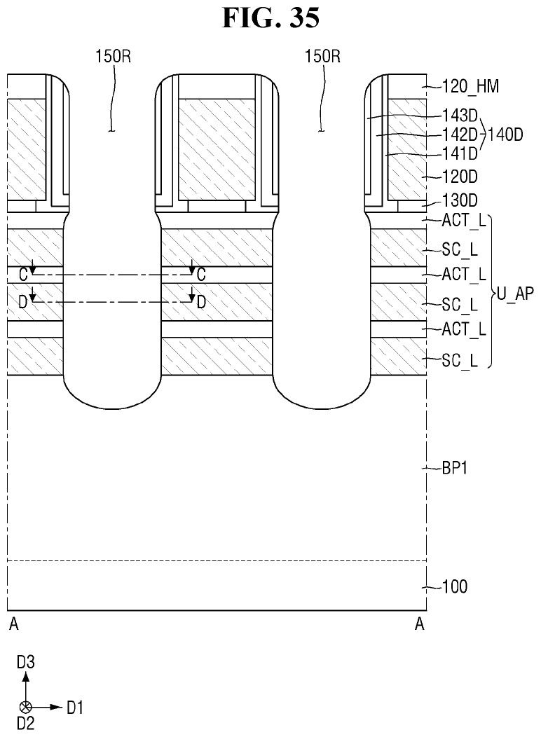

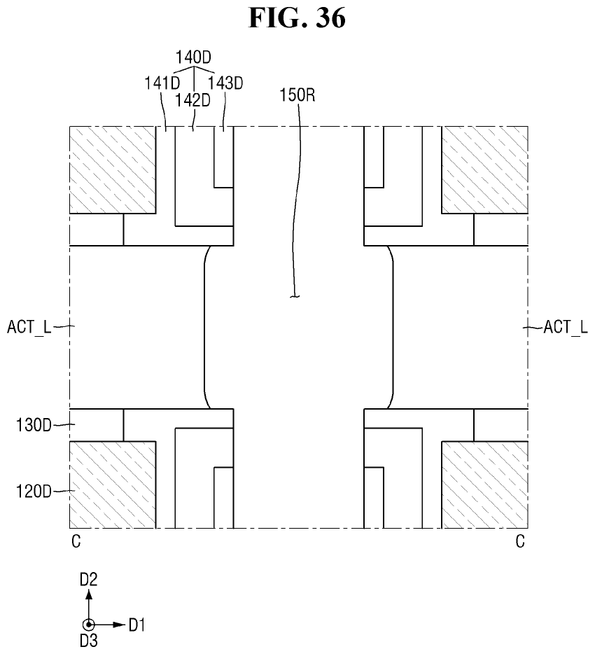

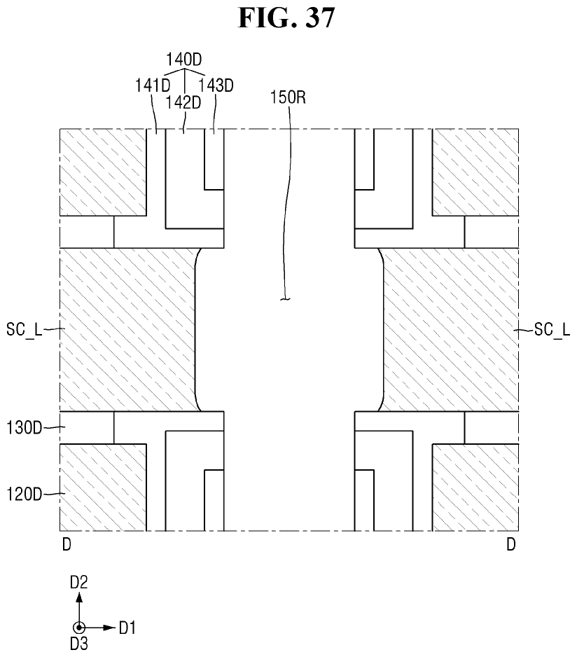

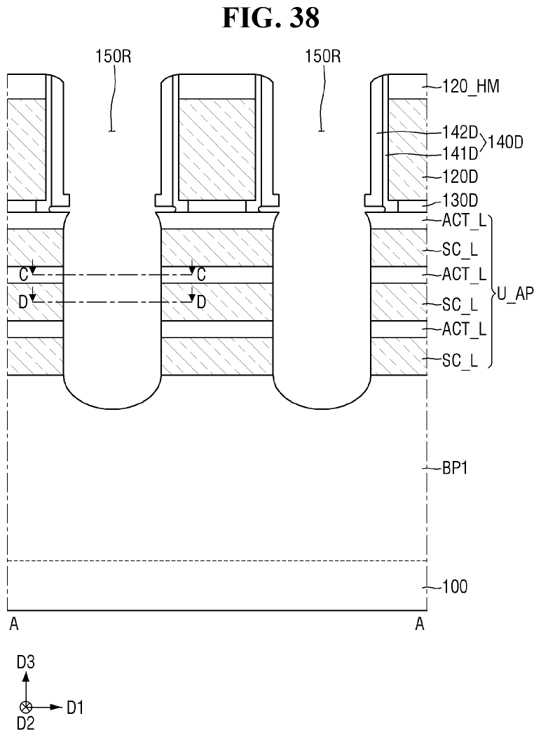

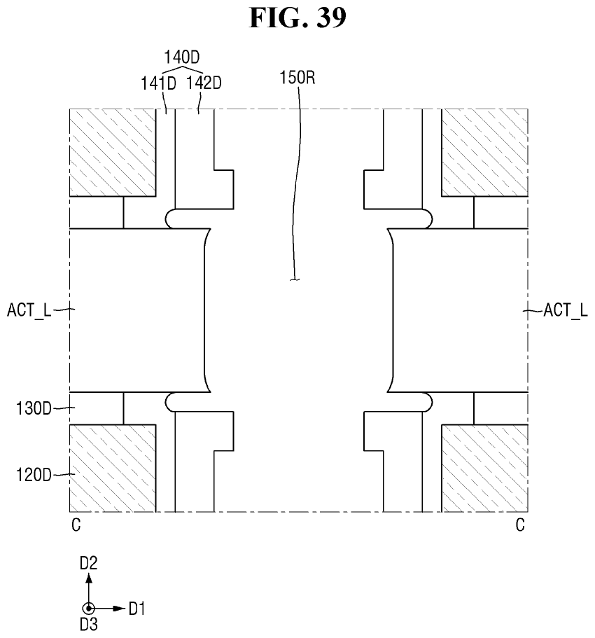

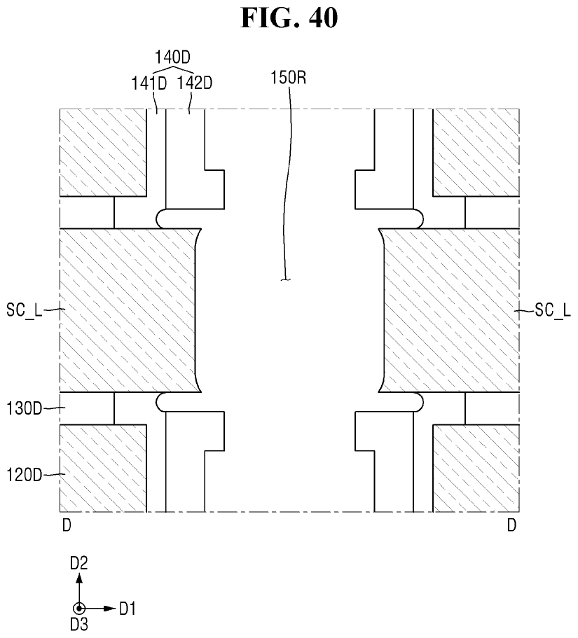

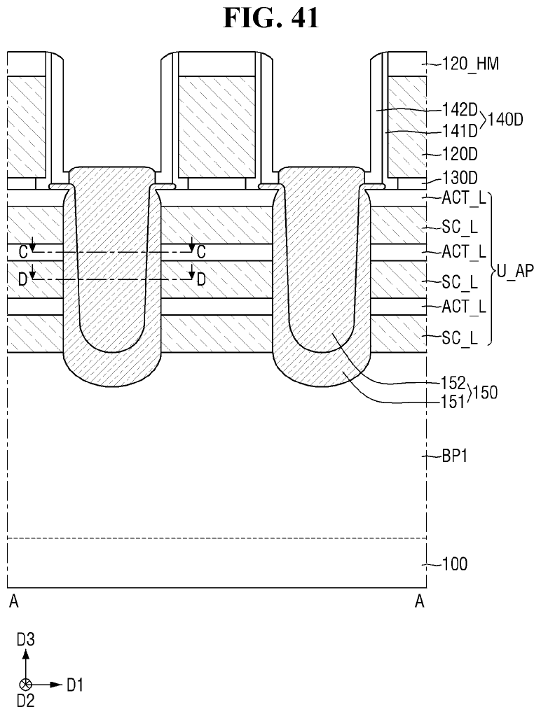

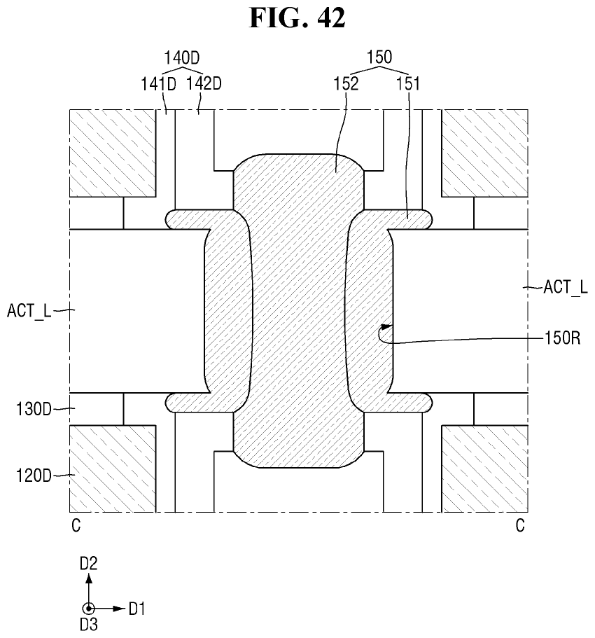

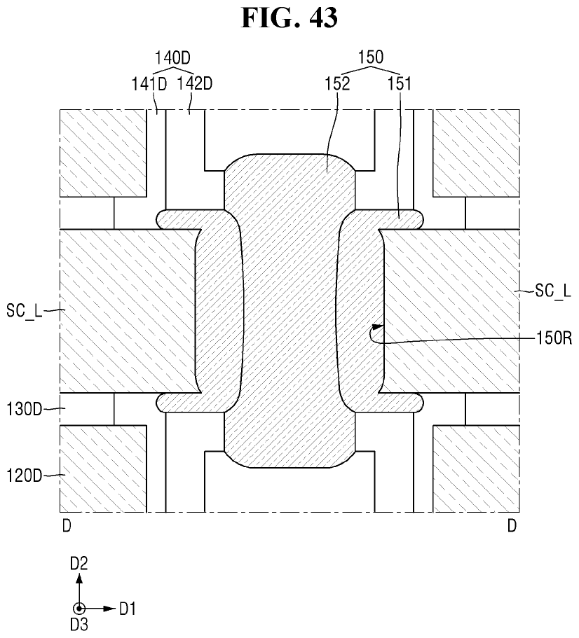

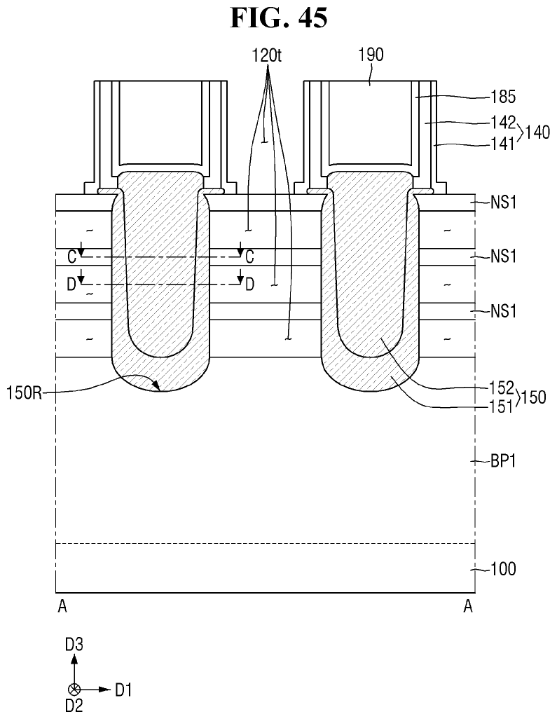

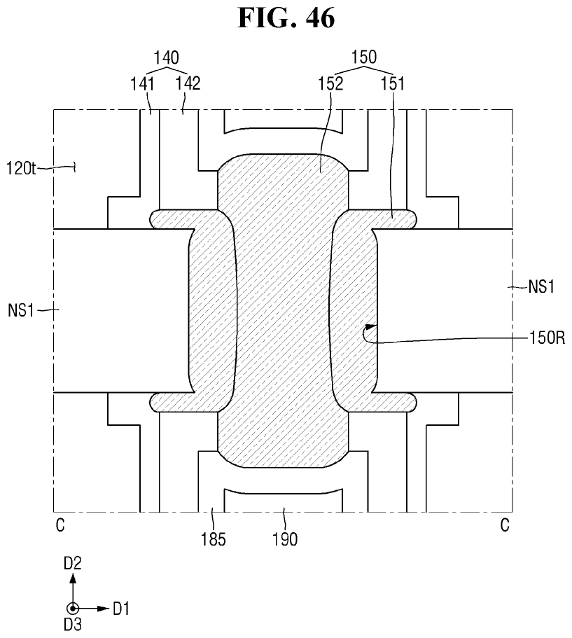

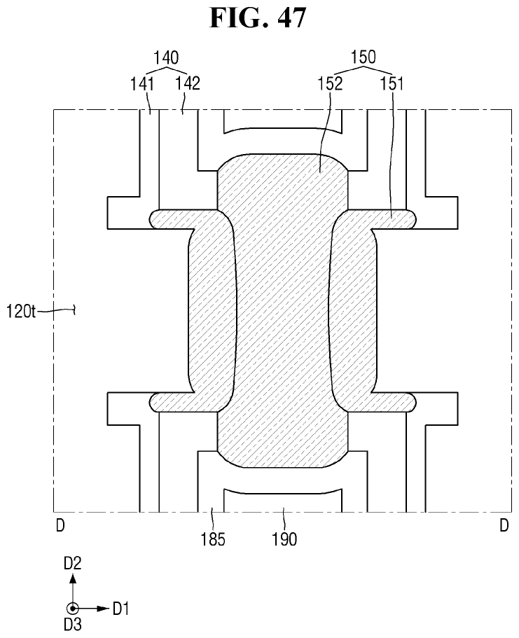

FIGS. 34 to 47 are intermediate step views for describing a method for manufacturing a semiconductor device according to some example embodiments. FIGS. 34, 35, 38, 41, 44, and 45 may be cross-sectional views taken along line A-A of FIG. 1. FIGS. 36 and 37 are plan views taken along lines C-C and D-D of FIG. 35. FIGS. 39 and 40 are plan views taken along lines C-C and D-D of FIG. 38. FIGS. 42 and 43 are plan views taken along lines C-C and D-D of FIG. 41. FIGS. 46 and 47 are plan views taken along lines C-C and D-D of FIG. 45.

Referring to FIG. 34, a first lower pattern BP1 and an upper pattern structure U_AP may be formed on the substrate 100.

The first lower pattern BP1 may extend in the first direction D1. The upper pattern structure U_AP may be disposed on the first lower pattern BP1. The upper pattern structure U_AP may include sacrificial patterns SC_L and active patterns ACT_L alternately stacked on the first lower pattern BP1. For example, the sacrificial pattern SC_L may include a silicon-germanium film. The active pattern ACT_L may include a silicon film. A fraction of germanium of the sacrificial pattern SC_L is greater than a fraction of germanium of the semiconductor liner film 151 of FIG. 2.

Subsequently, a dummy gate structure extending in the second direction D2 is formed on the upper pattern structure U_AP. The dummy gate structure may include a dummy gate insulating film 130D, a dummy gate electrode 120D, and a dummy gate capping film 120_HM. While the dummy gate structure is being formed, the dummy gate insulating film 130D may be undercut to a lower portion of the dummy gate electrode 120D. Through this, an undercut region 130D_UR may be formed on the lower portion of the dummy gate electrode 120D.

The dummy gate insulating film 130D may include, for example, silicon oxide, but is not limited thereto. The dummy gate electrode 120D may include, for example, polysilicon, but is not limited thereto. The dummy gate capping film 120_HM may include, for example, silicon nitride, but is not limited thereto.

Unlike illustrated, the dummy gate insulating film 130D may not be undercut to the lower portion of the dummy gate electrode 120D.

Referring to FIGS. 35 to 37, a dummy gate spacer 140D may be formed on a sidewall of the dummy gate electrode 120D.

The dummy gate spacer 140D may include a first dummy spacer 141D, a second dummy spacer 142D, and a third dummy spacer 143D. The first dummy spacer 141D may fill the undercut region (130D_UR in FIG. 34) on the lower portion of the dummy gate electrode 120D.

A first dummy insulating film, a second dummy insulating film, and a third dummy insulating film may be sequentially formed along a profile of the upper pattern structure U_AP and a profile of the dummy gate electrode 120D. Subsequently, the first dummy insulating film, the second dummy insulating film, and the third dummy insulating film may be etched through an anisotropic etching process. Through this, the first dummy spacer 141D, the second dummy spacer 142D, and the third dummy spacer 143D may be formed. The second dummy spacer 142D may include a material having an etch selectivity with respect to the first dummy spacer 141D and the third dummy spacer 143D.

The first dummy spacer 141D may include an extending portion extending along a sidewall of the dummy gate electrode 120D and a protruding portion protruding from the extending portion of the first dummy spacer 141D in the first direction D1. The second dummy spacer 142D may include an extending portion extending along a sidewall of the dummy gate electrode 120D and a protruding portion protruding from the extending portion of the second dummy spacer 142D in the first direction D1.

A first source/drain recess 150R may be formed in the upper pattern structure U_AP by using the dummy gate spacer 140D and the dummy gate electrode 120D as a mask.

A portion of the first source/drain recess 150R may be formed in the first lower pattern BP1.

Referring to FIGS. 38 to 40, the third dummy spacer 143D may be removed.

While the third dummy spacer 143D is removed, a portion of the protruding portion of the first dummy spacer 141D may be removed. As a portion of the protruding portion of the first dummy spacer 141D is removed, a spacer intent region may be formed between the active pattern ACT_L and the second dummy spacer 142D and between the sacrificial pattern SC_L and the second dummy spacer 142D.

Referring to FIGS. 41 to 43, a semiconductor liner film 151 may be formed along a profile of the first source/drain recess 150R.

The semiconductor liner film 151 may be in direct contact with the sacrificial pattern SC_L and the active pattern ACT_L. The semiconductor liner film 151 may fill the spacer indent region between the active pattern ACT_L and the second dummy spacer 142D and between the sacrificial pattern SC_L and the second dummy spacer 142D.

As the semiconductor liner film 151 fills the spacer indent region, a thickness of the semiconductor liner film 151 in contact with the dummy gate spacer 140D may increase.

In FIG. 47, while the sacrificial pattern SC_L is removed, an etchant for removing the sacrificial pattern SC_L may permeate through the vicinity of a boundary between the first gate spacer 140 and the semiconductor liner film 151. The permeating etchant may etch the semiconductor filling film 152, and thus reliability and performance of the semiconductor device may deteriorate.

However, the semiconductor liner film 151 may remain thick at a boundary with the first gate spacer 140. Through this, while the sacrificial pattern SC_L is removed, the etchant for removing the sacrificial pattern SC_L may be prevented from permeating into the semiconductor filling film 152 through the boundary between the first gate spacer 140 and the semiconductor liner film 151.

Subsequently, the semiconductor filling film 152 is formed on the semiconductor liner film 151. Through this, a first source/drain pattern 150 may be formed in the first source/drain recess 150R.

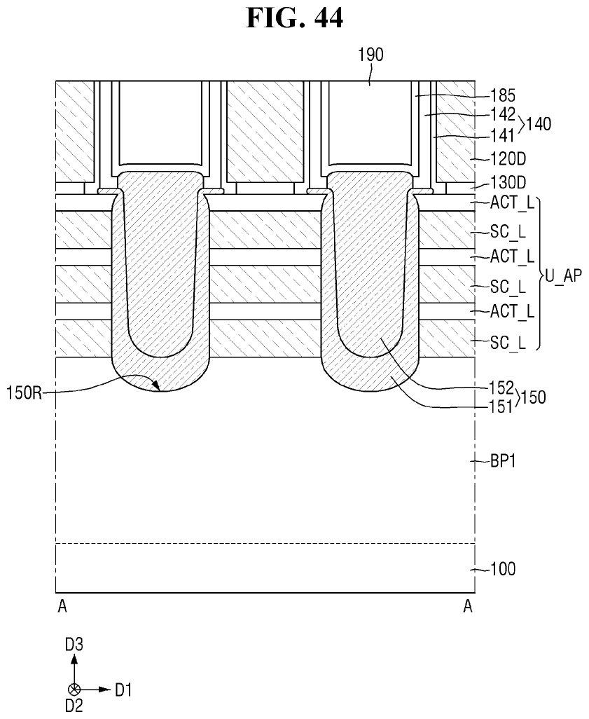

Referring to FIG. 44, a source/drain etch stop film 185 and a first interlayer insulating film 190 may be sequentially formed on the first source/drain pattern 150.

The source/drain etch stop film 185 and the first interlayer insulating film 190 are sequentially formed on the dummy gate spacer 140D.

Subsequently, an upper surface of the dummy gate electrode 120D is exposed by removing a portion of the first interlayer insulating film 190, a portion of the source/drain etch stop film 185, and the dummy gate capping film 120_HM.

While the upper surface of the dummy gate electrode 120D is exposed, a first gate spacer 140 may be formed. The first dummy spacer 141D may be a first spacer 141. The second dummy spacer 142D may be a second spacer 142.

Referring to FIGS. 44 to 47, the upper pattern structure U_AP between the first gate spacers 140 may be exposed by removing the dummy gate insulating film 130D and the dummy gate electrode 120D.

Subsequently, a first sheet pattern NS1 may be formed by removing the sacrificial pattern SC_L. Through this, a first gate trench 120t is formed between the first gate spacers 140.

Subsequently, referring to FIG. 2, a first gate insulating film 130 and a first gate electrode 120 may be formed in the first gate trench 120t. In addition, a first gate capping pattern 145 may be formed.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device comprising:
an active pattern comprising a lower pattern extending a first direction and a plurality of sheet patterns spaced apart from the lower pattern in a second direction;
a plurality of gate structures disposed on the active pattern and comprising gate electrodes extending in a third direction and gate spacers disposed on sidewalls of the gate electrodes; and
a source and drain pattern disposed between the plurality of gate structures adjacent to each other and comprising a semiconductor liner film and a semiconductor filling film on the semiconductor liner film,
wherein an uppermost sheet pattern of the plurality of sheet patterns comprises an upper surface and a bottom surface opposite to the upper surface, in the second direction,
the bottom surface of the uppermost sheet pattern faces the lower pattern, and the semiconductor liner film covers a portion of the upper surface of the uppermost sheet pattern.

2. The semiconductor device of claim 1, wherein the gate spacer comprises a first spacer and a second spacer,
the first spacer is disposed between the gate electrode and the second spacer,
the second spacer comprises an extending portion of the second spacer extending in the third direction along the sidewall of the gate electrode, and a protruding portion of the second spacer protruding from the extending portion of the second spacer in the first direction,
the protruding portion of the second spacer comprises a first surface facing the sheet pattern and a second surface opposite to the first surface of the protruding portion of the second spacer, and
the semiconductor liner film is in contact with the first surface of the protruding portion of the second spacer.

3. The semiconductor device of claim 2, further comprising a etch stop film disposed on the source and drain pattern and in contact with the second spacer,
wherein the etch stop film is in contact with the second surface of the protruding portion of the second spacer.

4. The semiconductor device of claim 2, wherein a portion of the semiconductor filling film is disposed on the second surface of the protruding portion of the second spacer.

5. The semiconductor device of claim 2, wherein the first spacer comprises an extending portion of the first spacer extending in the third direction along the sidewall of the gate electrode, and a protruding portion of the first spacer protruding from the extending portion of the first spacer in the first direction.

6. The semiconductor device of claim 2, wherein the first spacer has an I shape in a cross-sectional view.

7. The semiconductor device of claim 2, wherein the first spacer has a T shape rotated by 180 degrees in a cross-sectional view.

8. The semiconductor device of claim 1, wherein each of the plurality of gate structure comprises a gate insulating film disposed between the gate spacer and the gate electrode, and
the gate insulating film is in contact with the semiconductor liner film.

9. The semiconductor device of claim 1, wherein the source and drain pattern further comprises a semiconductor insertion film disposed between the semiconductor liner film and the semiconductor filling film, and
the semiconductor liner film, the semiconductor filling film, and the semiconductor insertion film comprise silicon-germanium.

10. A semiconductor device comprising:
an active pattern comprising a lower pattern extending in a first direction and a plurality of sheet patterns spaced apart from the lower pattern in a second direction;
a plurality of gate structures disposed on the active pattern, and comprising gate electrodes extending in a third direction, gate spacers disposed on sidewalls of the gate electrodes, and gate insulating films disposed between the gate spacers and the gate electrodes; and
a source and drain pattern disposed between the plurality of gate structures adjacent to each other and comprising a semiconductor liner film in contact with the gate insulating film and a semiconductor filling film on the semiconductor liner film,
wherein the semiconductor liner film comprises a central portion and protruding portions disposed on both sides of the central portion of the semiconductor liner film in a plan view, and
the protruding portion of the semiconductor liner film protrudes in the first direction toward the gate electrode.

11. The semiconductor device of claim 10, wherein a width of a contact surface where the semiconductor liner film and the gate insulating film are in contact in the third direction is less than a width of the semiconductor liner film in the third direction.

12. The semiconductor device of claim 10, wherein the plurality of sheet patterns comprise upper surfaces and bottom surfaces opposite to the upper surfaces in the second direction, respectively,
the plurality of sheet patterns comprise sidewalls connecting the upper surfaces and the bottom surfaces of the plurality of sheet patterns in the third direction, respectively, and
the semiconductor liner film covers a portion of the sidewalls of the plurality of sheet patterns.

13. The semiconductor device of claim 12, wherein the protruding portion of the semiconductor liner film is in contact with the sidewalls of the plurality of sheet patterns.

14. The semiconductor device of claim 10, wherein the gate spacer comprises a first spacer and a second spacer,
the first spacer is disposed between the gate electrode and the second spacer,
the second spacer comprises an extending portion of the second spacer extending in the third direction along the sidewall of the gate electrode, and a protruding portion of the second spacer protruding from the extending portion of the second spacer in the first direction, and
the semiconductor liner film is in contact with the protruding portion of the second spacer.

15. The semiconductor device of claim 14, wherein the protruding portion of the semiconductor liner film overlaps the first spacer in the first direction.

16. The semiconductor device of claim 14, wherein the first spacer comprises an extending portion of the first spacer extending in the third direction along the sidewall of the gate electrode, and a protruding portion of the first spacer protruding from the extending portion of the first spacer in the first direction.

17. The semiconductor device of claim 16, wherein the protruding portion of the first spacer protrudes toward the gate electrode.

18. The semiconductor device of claim 14, wherein the first spacer has an I shape in a plan view.

19. A semiconductor device comprising:
an active pattern comprising a lower pattern extending a first direction and a plurality of sheet patterns spaced apart from the lower pattern in a second direction;
a plurality of gate structures disposed on the active pattern and comprising gate electrodes extending in a third direction and gate spacers disposed on sidewalls of the gate electrodes; and
a source and drain pattern disposed between the plurality of gate structures adjacent to each other and comprising a semiconductor liner film and a semiconductor filling film on the semiconductor liner film,
wherein the gate spacer comprises a first spacer and a second spacer disposed between the first spacer and the gate electrode,
the first spacer comprises an extending portion of the first spacer extending in the third direction along the sidewall of the gate electrode, and a protruding portion of the first spacer protruding from the extending portion of the first spacer in the first direction,
the protruding portion of the first spacer comprises a first surface facing the plurality of sheet patterns and a second surface opposite to the first surface of the protruding portion of the first spacer,
an uppermost sheet pattern of the plurality of sheet patterns comprises an upper surface and a bottom surface opposite to the upper surface, in the second direction,
the bottom surface of the uppermost sheet pattern faces the lower pattern, and
a portion of the semiconductor liner film is recessed between the upper surface of the uppermost sheet pattern and the first surface of the protruding portion of the first spacer.

20. The semiconductor device of claim 19, wherein the second spacer comprises an extending portion of the second spacer extending in the third direction along the sidewall of the gate electrode, and a protruding portion of the second spacer protruding from the extending portion of the second spacer in the first direction, and
the protruding portion of the second spacer protrudes toward the gate electrode.
